(19) United States
(12) Patent Application Publication
(10) Pub. No.: US 2020/0183276 A1
(43) Pub. Date: Jun. 11, 2020

(54) Photoactive Catalyst Compositions

(71) Applicants: California Institute of Technology, Pasadena, CA (US); PolySpectra, Inc., Berkeley, CA (US)

(72) Inventor: Raymond A. Weitekamp, Glendale, CA (US)

(21) Appl. No.: 16/784,790

(22) Filed: Feb. 7, 2020

Related U.S. Application Data
(62) Division of application No. 15/692,229, filed on Aug. 31, 2017, now abandoned.
(60) Provisional application No. 62/383,146, filed on Sep. 2, 2016.

(51) Int. Cl. G03F 7/029; B01J 31/00; G03F 7/20; G03F 7/00; G03F 7/095; G03F 7/027; G03F 7/004; C07F 15/00; B01J 23/46

(52) U.S. Cl. CPC G03F 7/029; B01J 31/00; G03F 7/2051; G03F 7/201; G03F 7/0037; G03F 7/095; B01J 31/2273; G03F 7/20; G03F 7/0042; C07F 15/0046; B01J 23/462; B01J 2531/821; B01J 2231/543; G03F 7/027

(57) ABSTRACT

The present disclosure is directed to photosensitive compositions ‘Fischer-type’ ruthenium carbene catalysts containing chelated 2,2′-bipyridine ligands and methods of using the same. These catalysts are surprisingly active even when using relatively low intensity diode light sources. The 2,2′-bipyridine-chelated ruthenium photocatalysts show reactivity at substantially lower exposure levels than other photoactive chelating dinitrogen ligands of similar structure. The present disclosure is further directed to novel photosensitive compositions, their use as photoresists, and methods related to patterning polymer layers on substrates.

### CROSS REFERENCE TO RELATED APPLICATIONS

This application is a divisional application of U.S. patent application Ser. No. 15/692,229, filed Aug. 31, 2017 that claims the benefit of priority to U.S. Patent Application Ser. No. 62/383,146, filed Sep. 2, 2016, the contents of which are each incorporated by reference in their entirety for any and all purposes.

### GOVERNMENT RIGHTS

This invention was made with government support under Grant No. 16447467 awarded by the National Science Foundation and Grant No. DE-AC05-060R23100 awarded by the US Department of Energy. The government has certain rights in the invention.

### TECHNICAL FIELD

The present disclosure relates to functionalized photolithographic compositions. It also relates to metathesis reactions catalyzed by organometallic coordination compounds, particularly by Fischer-type ruthenium carbene catalysts, and in particular those containing chelating 2,2′-bipyridine ligands.

### BACKGROUND

Photolithography is the patterning technique at the foundation of microfabrication, the core of modern integrated circuit technology. In a photoresist, the pattern of optical irradiation is converted to a pattern of chemically distinct regions, typically through photoinitiated functional group cleavage or crosslinking. Many modern photoresists employ the concept of “chemical amplification,” in which a photogenerated catalyst reacts with many sites. For example, photoacid generators are commonly employed in chemically amplified resists, either to catalyze a ring opening polymerization or initiate a cascade of deprotective bond scissions within a polymer matrix, imparting new solubility properties to the irradiated regions. While there are a number of light-mediated reactions that could be, in principle, employed in photolithography, very few have been implemented. Despite the fact that there are hundreds of commercially available photoresists, the functional diversity amongst these materials is severely limited. In most applications, the photoresist serves the sole purpose of a sacrificial mask or mold; very rarely is the resist material incorporated as a structural element or chemically functional interface. The ability to generate new kinds of chemically functional materials directly via photolithography would enable a host of new applications, for example in microelectromechanical systems (MEMS), microfluidics, patterned biomaterials and artificial optical materials. Olefin metathesis is a robust synthetic methodology that has led to new polymeric materials with many applications, such as drug delivery, organic electronics, and photonic crystals.

### SUMMARY

Certain embodiments provide photosensitive compositions, each composition comprising a ruthenium carbene metathesis catalyst of Formula (I) or a geometric isomer thereof:

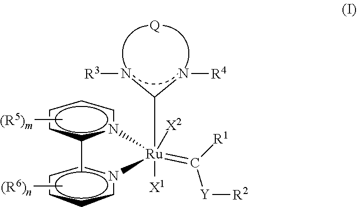

admixed within a polymerizable material matrix comprising at least one unsaturated organic precursor, including ROMP or cross-metathesis precursors;

wherein

X¹ and X² are independent anionic ligands;

Y is O, N—R¹, or S, preferably O; and

Q is a two-atom linkage having the structure —CR¹¹R¹²—CR¹³R¹⁴— or —CR¹¹═CR¹³—, preferably —CR¹¹R¹²—CR¹³R¹⁴—, wherein R¹¹, R¹², R¹³, and R¹⁴ are independently hydrogen, optionally substituted hydrocarbyl, optionally substituted heteroatom-containing hydrocarbyl, or a functional group;

R¹ and R² are independently hydrogen, optionally substituted hydrocarbyl, optionally substituted heteroatom-containing hydrocarbyl, or may be linked together to form an optionally substituted cyclic aliphatic group;

R³ and R⁴ are independently optionally substituted hydrocarbyl, preferably an optionally substituted adamantyl or substituted phenyl; and

R⁵ and R⁶ are independently H or electron-withdrawing or electron-donating groups, including C₁₋₂₄alkyl, C₁₋₂₄alkoxy, C₁₋₂₄fluoroalkyl (including perfluoroalkyl), C₁₋₂₄fluoroalkoxy (including perfluoroalkoxy), C₁₋₂₄alkylhydroxy, C₁₋₂₄alkoxyhydroxy, C₁₋₂₄fluoroalkylhydroxy(including perfluoroalkylhydroxy), C₁₋₂₄fluoroalkoxyhydroxy (including perfluoroalkoxyhydroxy) halo (e.g., F, Cl, Br), cyano, nitro, or hydroxyl, silyl, or phosphonyl; and

m and n are independently 1, 2, 3, or 4.

R⁵ and R⁶ can also independently be optionally substituted aryl, alkaryl, aralkyl, aryloxy, alkaryloxy, aralkoxy, primary amine, secondary amine, tertiary amine, amido, alkylcarbonyl, alkoxycarbonyl, or aminocarbonyl

In some of these compositions one or both of R⁵ and R⁶ is H. In some of these compositions m=n=1. In some of these compositions one or both of R⁵ and R⁶ is C₁₋₁₂alkyl, C₁₋₁₂fluoroalkyl (including perfluoroalkyl), C₁₋₁₂fluoroalkoxy (including perfluoroalkoxy), C₁₋₁₂alkylhydroxy, C₁₋₁₂alkoxyhydroxy, C₁₋₁₂fluoroalkylhydroxy(including perfluoroalkylhydroxy), C₁₋₁₂fluoroalkoxyhydroxy (including perfluoroalkoxyhydroxy), F, Cl, Br, or hydroxy. In some embodiments, R⁵ and R⁶ are present in the 3,3′ or 4,4′ or 5,5′ or 6,6′ position, respectively

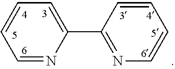 [SMILES: c1ccc(-c2ccccn2)nc1]

In related embodiments, the metathesis catalyst comprises a compound having a structure of IA, or a geometric isomer thereof:

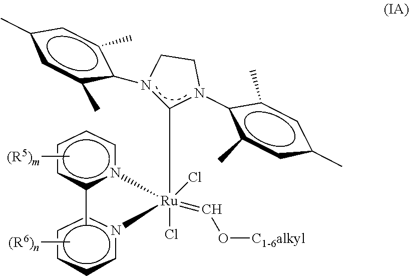

The bipyridinyl ruthenium metathesis catalysts of Formula (I) may be added as-described or generated in-situ.

In other specific embodiments, the metathesis catalyst of the photosensitive composition, upon activation by irradiation of light of at at least one wavelength in a range of from about 250 nm to about 800 nm, can crosslink or polymerize at least one of the unsaturated organic precursors.

Other embodiments provide methods of patterning polymeric image on a substrate, each method comprising; (a) depositing a layer of one of the inventive photosensitive compositions on a substrate; (b) irradiating a portion of the layer of photosensitive composition with a light comprising at at least one wavelength in a range of from about 250 nm to about 800 nm nm, or a sub-range therewithin, so as to polymerize the irradiated portion of the layer, thereby providing polymerized and unpolymerized nor non-irradiated regions in the layer. In other embodiments, the methods further comprise removing the unpolymerized region of the pattern.

Still other embodiments provide photosensitive compositions, each further comprising and organometallic moiety having at least one alkene or one alkyne bond capable of metathesizing with the at least one unsaturated organic precursor. In some of these embodiments, the organometallic moiety comprises a Group 3 to Group 12 transition metal, preferably Fe, Co, Ni, Ti, Al, Cu, Zn, Ru, Rh, Ag, Ir, Pt, Au, or Hg, which may be capable of catalyzing a variety of organic and inorganic reactions.

Other embodiments provide photosensitive compositions, each also comprising any one or more of the more general range of bipyridinyl ruthenium metathesis catalyst admixed or dissolved within a polymerizable material matrix comprising at least one unsaturated organic precursor, each organic precursor having at least one alkene or one alkyne bond; where the at least one unsaturated organic precursor comprises a compound having a structure:

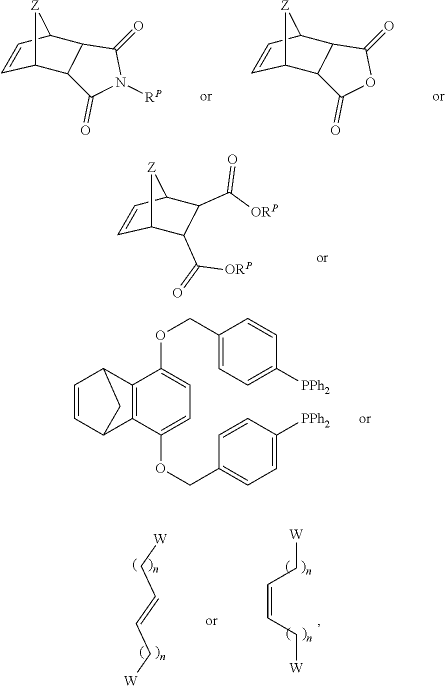

wherein

Z is —O— or C(Rₐ)(R_{b});

R^{P} is independently H; or C₁₋₆ alkyl optionally substituted at the distal terminus with —N(Rₐ)(R_{b}), —O—Rₐ, —C(O)O—Rₐ, —OC(O)—(C₁₋₆ alkyl), or —OC(O)—(C₆-10 aryl); or an optionally protected sequence of 3 to 10 amino acids (preferably including R-G-D or arginine-glycine-aspartic acid);

W is independently —N(Rₐ)(R_{b}), —O—Rₐ, or —C(O)O—Rₐ, —P(O)(ORₐ)₂, —SO₂(ORₐ), or SO₃⁻;

Rₐ and R_{b} are independently H or C₁₋₆ alkyl;

the C₆₋₁₀ aryl is optionally substituted with 1, 2, 3, 4, or 5 optionally protected hydroxyl groups (the protected hydroxyl groups preferably being benzyl); and

n is independently 1, 2, 3, 4, 5, or 6.

In some embodiments, the unsaturated organic precursor may be mono- or poly-functionalized

The methods of using these photosensitive composition may comprise: (a) depositing at least one layer of a photosensitive composition on a substrate; (b) irradiating a portion of the layer of photosensitive composition with a light comprising a wavelength in a range of from about 250 nm to about 800 nm, or a sub-range therewithin, so as to polymerize the irradiated portion of the layer, thereby providing a patterned layer of polymerized and unpolymerized regions. Such methods may also further comprise removing the unpolymerized region of the pattern.

Additional embodiments provide polymerized composition or an article of manufacture comprising the polymerize composition as prepared according to any one of the methods described herein. The compositions may be patterned layers or solid objects. In certain embodiments, the compositions can be used to form tissue scaffolds, the scaffolds being either alone or populated with tissue or cell populations (for example, stem cells) and methods of treatment using such scaffolds.

While the compositions and methods are suitable for forming patterned polymer layers, the same compositions and analogous methods can also be used to prepare three-dimensional structures. Certain embodiments provide, then, methods comprising; (a) depositing at least two layers of a composition having at least one alkene or alkyne capable of undergoing a metathesis polymerization or crosslinking reaction, at least one of which contains a catalyst of Formula (I), said deposition forming a stacked assembly; (b) irradiating at least a portion of the stacked assembly with light, such that light penetrates and irradiates at least two layers of the stacked assembly, under conditions sufficient to polymerize or crosslink at least portions of adjacent layers of the stacked assembly; wherein at least one layer contains a ruthenium carbene 2,2′-bipyridine complex as described herein.

### BRIEF DESCRIPTION OF THE DRAWINGS

The present application is further understood when read in conjunction with the appended drawings. For the purpose of illustrating the subject matter, there are shown in the drawings exemplary embodiments of the subject matter; however, the presently disclosed subject matter is not limited to the specific methods, devices, and systems disclosed. In addition, the drawings are not necessarily drawn to scale. In the drawings:

FIGS. 1A and 1B show structures of preferred catalysts of the present disclosure.

FIG. 2 show some of the bipyridine ligands tested in the Examples.

FIG. 3 show some of the phenanthroline ligands tested in the Examples.

FIG. 4A illustrates the dark stabilities of various latent ruthenium catalysts containing phenanthroline and bipyridine ligands. FIG. 4B shows the corresponding reactivites of those catalysts, as described in Example 1.

FIG. 5 is a photopolymer ‘working curve’ measuring the cure depth of the gelled material as a function of the dosage of light for a latent ruthenium catalyst containing bipyridine ligand, as described in Example 5.

FIG. 6 is a photopolymer ‘working curve’ measuring the cure depth of the gelled material as a function of the dosage of light for a latent ruthenium catalyst containing 4,4′-di-tert-butyl-2,2′-bipyridine ligand, as described in Example 6.

FIG. 7 is a depiction of testing protocol and results described in Examples 5 and 6.

### DETAILED DESCRIPTION OF ILLUSTRATIVE EMBODIMENTS

The present disclosure relates to method of metathesizing olefins using catalysts previously considered to be practically inactive. These methods provide for novel photosensitive compositions, their use as photoresists, and methods related to patterning polymer layers on substrates. Further, modifications to the compositions and method provide for an unprecedented functionalization of the compositions, useful for example in the preparation of sensors, drug delivery systems, and tissue scaffolds. The novel compositions and associated methods also provide for the opportunity to prepare 3-dimensional objects which provide new access to critically dimensioned devices, including for example photonic devices.

U.S. patent application Ser. No. 14/505,824, filed Oct. 3, 2014, describes the use of phenanthroline- and other aromatic diamine-based ruthenium metathesis catalysts as latent photoactivators. The present inventor has discovered that replacing the phenanthroline ligand with any one of a range of bipyridinyl ligands results in an unexpectedly higher activity of the resulting metathesis catalysts, allowing for lower loadings and the ability to use less intense light sources. The degree of enhancement in activity is so significant that it allows these ruthenium-bipyridine catalysts to operate under conditions where the corresponding phenantholine materials do not.

Despite the dramatic increase in photoactivity, all of the applications and products resulting from the use of the phenanthroline derivatives described in U.S. patent application Ser. No. 14/505,824 are expected to be applicable with these more photoactive bipyridine-substituted materials. For the sake of completeness, many of the descriptions in the 824 application are reiterated here.

The present disclosure may be understood more readily by reference to the following description taken in connection with the accompanying Figures and Examples, all of which form a part of this disclosure. It is to be understood that this disclosure is not limited to the specific products, methods, conditions or parameters described or shown herein, and that the terminology used herein is for the purpose of describing particular embodiments by way of example only and is not intended to be limiting of any claimed invention. Similarly, unless specifically otherwise stated, any description as to a possible mechanism or mode of action or reason for improvement is meant to be illustrative only, and the disclosure herein is not to be constrained by the correctness or incorrectness of any such suggested mechanism or mode of action or reason for improvement. Throughout this text, it is recognized that the descriptions refer to compositions and methods of making and using said compositions. That is, where the disclosure describes or claims a feature or embodiment associated with a composition or a method of making or using a composition, it is appreciated that such a description or claim is intended to extend these features or embodiment to embodiments in each of these contexts (i.e., compositions, methods of making, and methods of using).

In the present disclosure the singular forms “a,” “an,” and “the” include the plural reference, and reference to a particular numerical value includes at least that particular value, unless the context clearly indicates otherwise. Thus, for example, a reference to “a material” is a reference to at least one of such materials and equivalents thereof known to those skilled in the art, and so forth.

When a value is expressed as an approximation by use of the descriptor “about,” it will be understood that the particular value forms another embodiment. In general, use of the term “about” indicates approximations that can vary depending on the desired properties sought to be obtained by the disclosed subject matter and is to be interpreted in the specific context in which it is used, based on its function. The person skilled in the art will be able to interpret this as a matter of routine. In some cases, the number of significant figures used for a particular value may be one non-limiting method of determining the extent of the word “about.” In other cases, the gradations used in a series of values may be used to determine the intended range available to the term “about” for each value. Where present, all ranges are inclusive and combinable. That is, references to values stated in ranges include every value within that range.

It is to be appreciated that certain features of the disclosure which are, for clarity, described herein in the context of separate embodiments, may also be provided in combination in a single embodiment. That is, unless obviously incompatible or specifically excluded, each individual embodiment is deemed to be combinable with any other embodiment(s) and such a combination is considered to be another embodiment. Conversely, various features of the disclosure that are, for brevity, described in the context of a single embodiment, may also be provided separately or in any sub-combination. Finally, while an embodiment may be described as part of a series of steps or part of a more general structure, each said step may also be considered an independent embodiment in itself, combinable with others.

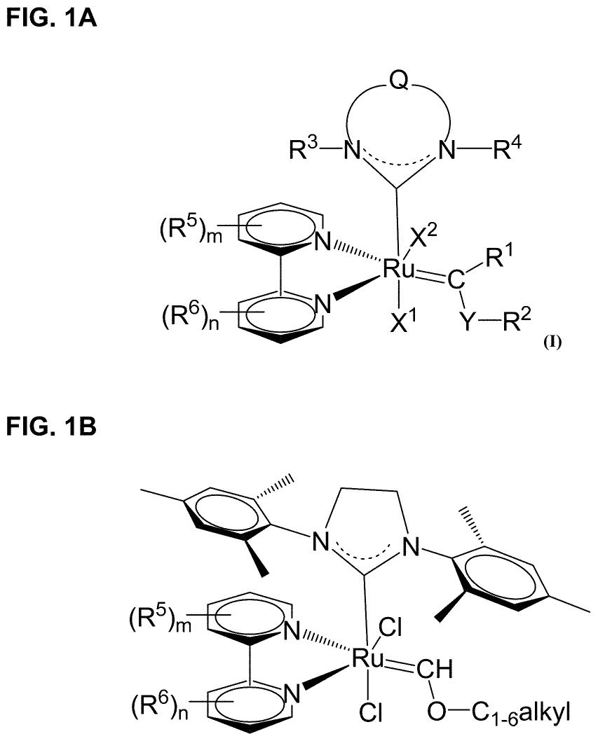

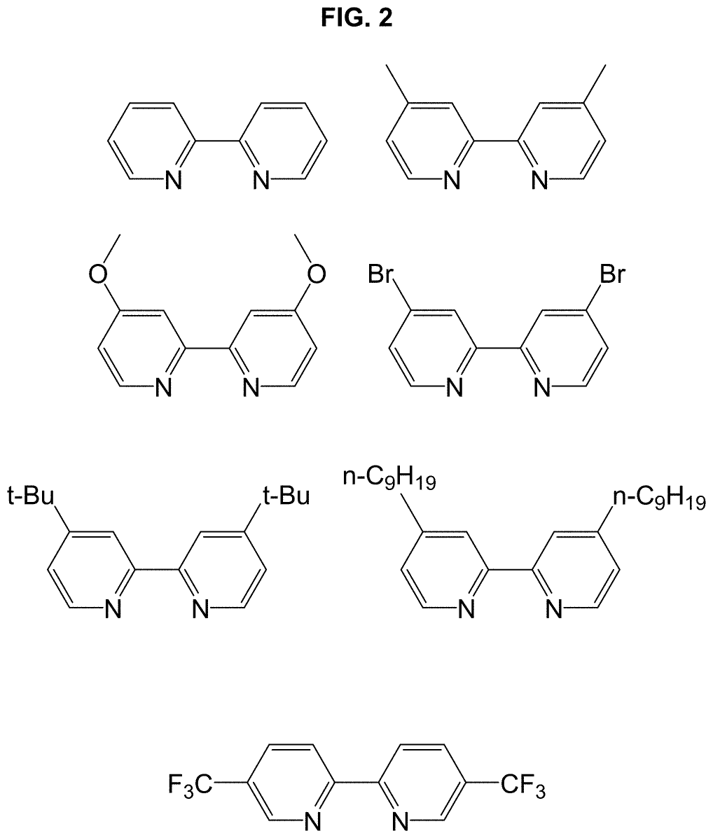

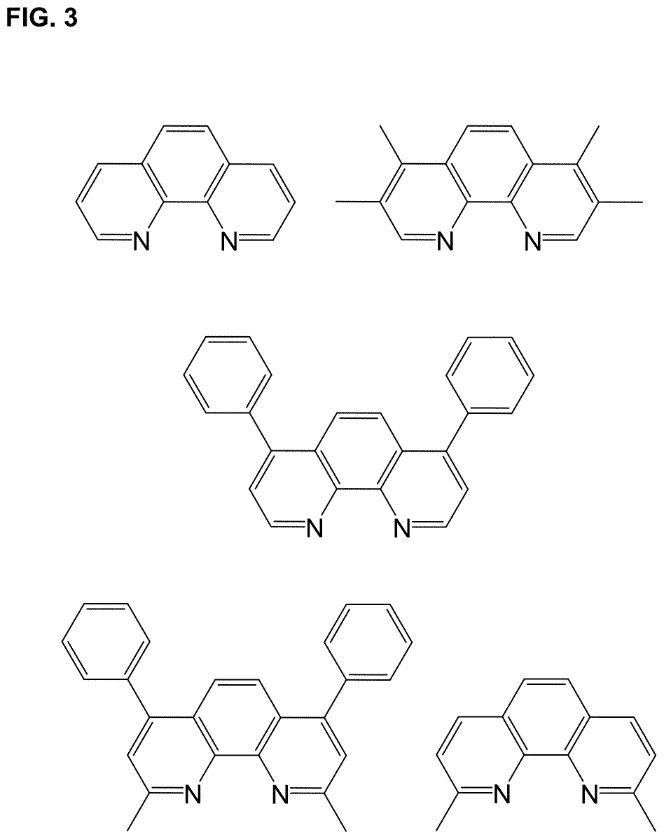

The transitional terms “comprising,” “consisting essentially of,” and “consisting” are intended to connote their generally in accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element, step, or ingredient not specified in the claim; and (iii) “consisting essentially of” limits the scope of a claim to the specified materials or steps “and those that do not materially affect the basic and novel characteristic(s)” of the claimed invention(s). Embodiments described in terms of the phrase “comprising” (or its equivalents), also provide, as embodiments, those which are independently described in terms of “consisting of” and “consisting essentially” of. For those embodiments provided in terms of “consisting essentially of,” the basic and novel characteristic(s) is the operability of the methods (or the compositions or devices derived therefrom) as providing a photochemically activated metathesis system using the bipyridine-ligated catalysts, for example, as shown in FIG. 1.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

Throughout this specification, words are to be afforded their normal meaning, as would be understood by those skilled in the relevant art. However, so as to avoid misunderstanding, the meanings of certain terms will be specifically defined or clarified.

The present invention(s) include a range of pre-polymerized compositions comprising at least one ruthenium carbene metathesis catalyst, methods of polymerizing these compositions, as well as their polymerized products, including the specific devices or articles derived therefrom. While not intending to be limited to any particular embodiment(s), these novel and non-obvious compositions may be described as including (1) ruthenium carbene metathesis catalysts containing bipyridine ligands, operable over the range of polymer compositions, structures and products; (2) olefin precursors and polymerizable matrices, each of which may include any one or more of the range of ruthenium carbene metathesis catalysts described herein; and (3) superstructures which can be prepared using any one or more of ruthenium carbene metathesis catalyst and one or more reactive polymers or polymerizable matrices. Each of these is described more fully below. For wording efficiency, the various elements of the disclosure(s) are described individually, though it should be recognized that the disclosure contemplates combinations thereof.

General Metathesis Description

The present disclosure describes compositions which are novel both in their choice of olefinic substrates and in the catalysts used to prepare the prepolymerized and polymerized compositions. These novel combinations of substrates and catalysts offer materials which exhibit properties or ways of handling these materials not previously recognized. In particular, these bipyridine-containing ruthenium catalysts exhibit a reactivity vastly and unexpectedly superior to their phenanthroline cousins. These substrates and catalysts will be discussed separately, but it should be appreciated that the present disclosure considers each combination to be within the scope of the present invention(s).

The present disclosure includes embodiments related to compositions and methods of metathesizing unsaturated organic precursors, each method comprising irradiating a Fischer-type carbene ruthenium metathesis catalyst of Formula (I) with at least one wavelength of light in the presence of at least one unsaturated organic precursor, so as to metathesize at least one alkene or one alkyne bond within the matrices of the at least one precursors. For purposes of the present disclosure, so-called “Fischer-type” carbenes are defined, as comprising a non-persistent carbene having pi-donor substituents, such as alkoxy and alkylated amino groups, as well as hydrogen and alkyl substituents on the non-persistent carbenoid carbon. Alkoxy and alkylated amino groups on the carbene carbon render Fischer-type carbenes, especially those of ruthenium, virtually inert relative to their “Schrock-type” cogeners. In fact, the addition of substituted vinyl ethers or vinyl amines, for example, can virtually inactivate a ruthenium metathesis catalyst containing a “Schrock-type” carbene, by forming the corresponding Fischer-type derivative. These Fischer-type carbene complexes are widely considered inactive due to the electronics of the carbene. In fact, ethyl vinyl ether is commonly used to quench ROMP (Ring Opening Metathesis Polymerization) reactions. The following descriptions now demonstrate that these Ruthenium complexes and their “quenched” derivatives undergo further chemistry when photochemically activated.

Catalysts

In certain embodiments, the Fischer-type carbene ruthenium metathesis catalyst used in the photochemically activated metathesis compositions is a metathesis catalyst of Formula (I):

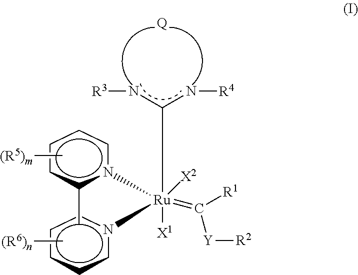

where:

X¹ and X² are independently anionic ligands;

Y is O, N—R¹, or S, preferably O; and

Q is a two-atom linkage having the structure —CR¹¹R¹²—CR¹³R¹⁴— or —CR¹¹═CR¹³—, preferably —CR¹¹R¹²—CR¹³R¹⁴—, wherein R¹¹, R¹², R¹³, and R¹⁴ are independently hydrogen an an optionally substituted hydrocarbyl;

R¹ and R² are independently hydrogen or optionally substituted hydrocarbyl, or R¹ and R² may be linked together to form an optionally substituted cyclic aliphatic group;

R³ and R⁴ are independently optionally substituted hydrocarbyl; and

R⁵ and R⁶ are independently H or electron-withdrawing or electron-donating groups, including C₁₋₂₄alkyl, C₁₋₂₄alkoxy, C₁₋₂₄fluoroalkyl, C₁₋₂₄fluoroalkoxy, C₁₋₂₄alkylhydroxy, C₁₋₂₄alkoxyhydroxy, C₁₋₂₄fluoroalkylhydroxy(including perfluoroalkylhydroxy), C₁₋₂₄fluoroalkoxyhydroxy, halo, cyano, nitro, or hydroxy; and

m and n are independently 1, 2, 3, or 4.

The ruthenium carbene metathesis catalyst of Formula (I) may be added as described here or generated in situ as described herein. The independent X¹ and X² are anionic ligands are believed to be positioned cis with respect to one another, though the compounds may also be present as geometric isomers of the structure as presented.

X¹ and X² are anionic ligands, and may be the same or different, or are linked together to form a cyclic group, typically although not necessarily a five- to eight-membered ring. In preferred embodiments, X¹ and X² are each independently hydrogen, halide, or one of the following groups: C₁-C₂₀ alkyl, C₅-C₂₄ aryl, C₁-C₂₀ alkoxy, C₅-C₂₄ aryloxy, C₂-C₂₀ alkoxycarbonyl, C₆-C₂₄ aryloxycarbonyl, C₂-C₂₄ acyl, C₂-C₂₄ acyloxy, C₁-C₂₀ alkylsulfonato, C₅-C₂₄ arylsulfonato, C₁-C₂₀ alkylsulfanyl, C₅-C₂₄ arylsulfanyl, C₁-C₂₀ alkylsulfinyl, NO₃, —N═C═O, —N═C═S, or C₅-C₂₄ arylsulfinyl. Optionally, X¹ and X² may be substituted with one or more moieties selected from C₁-C₁₂ alkyl, C₁-C₁₂ alkoxy, C₅-C₂₄ aryl, and halide, which may, in turn, with the exception of halide, be further substituted with one or more groups selected from halide, C₁-C₆ alkyl, C₁-C₆ alkoxy, and phenyl. In more preferred embodiments, X¹ and X² are halide, benzoate, C₂-C₆ acyl, C₂-C₆ alkoxycarbonyl, C₁-C₆ alkyl, phenoxy, C₁-C₆ alkoxy, C₁-C₆ alkylsulfanyl, aryl, or C₁-C₆ alkylsulfonyl. In even more preferred embodiments, X¹ and X² are each halide, CF₃CO₂, CH₃CO₂, CFH₂CO₂, (CH₃)₃CO, (CF₃)₂(CH₃)CO, (CF₃)(CH₃)₂CO, PhO, MeO, EtO, tosylate, mesylate, or trifluoromethane-sulfonate. In the most preferred embodiments, X¹ and X² are each chloride.

R¹ and R² are independently selected from hydrogen, hydrocarbyl (e.g., C₁-C₂₀ alkyl, C₂-C₂₀ alkenyl, C₂-C₂₀ alkynyl, C₅-C₂₄ aryl, C₆-C₂₄ alkaryl, C₆-C₂₄ aralkyl, etc.), substituted hydrocarbyl (e.g., substituted C₁-C₂₀ alkyl, C₂-C₂₀ alkenyl, C₂-C₂₀ alkynyl, C₅-C₂₄ aryl, C₆-C₂₄ alkaryl, C₆-C₂₄ aralkyl, etc.), heteroatom-containing hydrocarbyl (e.g., heteroatom-containing C₁-C₂₀ alkyl, C₂-C₂₀ alkenyl, C₂-C₂₀ alkynyl, C₅-C₂₄ aryl, C₆-C₂₄ alkaryl, C₆-C₂₄ aralkyl, etc.), and substituted heteroatom-containing hydrocarbyl (e.g., substituted heteroatom-containing C₁-C₂₀ alkyl, C₂-C₂₀ alkenyl, C₂-C₂₀ alkynyl, C₅-C₂₄ aryl, C₆-C₂₄ alkaryl, C₆-C₂₄ aralkyl, etc.), and functional groups. R¹ and R² may also be linked to form a cyclic group. Generally, such a cyclic group will contain 4 to 12, preferably 5, 6, 7, or 8 ring atoms. In certain embodiments, R² is not hydrogen.

In some embodiments, R¹ is hydrogen and R² is selected from C₁-C₂₀ alkyl, C₂-C₂₀ alkenyl, and C₅-C₂₄ aryl, more preferably C₁-C₆ alkyl, C₂-C₆ alkenyl, and C₅-C₁₄ aryl. Still more preferably, R² is phenyl, methyl, ethyl, isopropyl, or t-butyl, optionally substituted with one or more moieties selected from C₁-C₆ alkyl, C₁-C₆ alkoxy, phenyl, and a functional group Fn as defined earlier herein. Most preferably, R² is phenyl or ethyl optionally substituted with one or more moieties selected from methyl, ethyl, chloro, bromo, iodo, fluoro, nitro, dimethylamino, methyl, methoxy, and phenyl. Optimally, R² is phenyl, ethyl, propyl, or butyl.

In certain of these embodiments, Ru═C(R)(Y—R²) moiety is a substituted vinyl ether carbene. In independent embodiments, R² is C₁₋₆ alkyl, preferably ethyl, propyl, or butyl. In other embodiments, R¹ is H, R² is C₁₋₆ alkyl, and Y is O.

In certain of embodiments, the moiety:

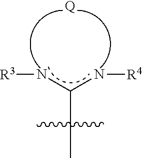

is an N-heterocyclic carbene (NHC) ligand. In some embodiments, R³ and R⁴ are as defined above, with preferably at least one of R³ and R⁴, and more preferably both R³ and R⁴, being alicyclic or aromatic of one to about five rings, and optionally containing one or more heteroatoms and/or substituents. Q is a linker, typically a hydrocarbylene linker, including substituted hydrocarbylene, heteroatom-containing hydrocarbylene, and substituted heteroatom-containing hydrocarbylene linkers, wherein two or more substituents on adjacent atoms within Q may also be linked to form an additional cyclic structure, which may be similarly substituted to provide a fused polycyclic structure of two to about five cyclic groups. Q is often, although not necessarily, a two-atom linkage or a three-atom linkage.

Examples of N-heterocyclic carbene (NHC) ligands and acyclic diaminocarbene ligands include, but are not limited to, the following where DIPP or DiPP is diisopropylphenyl and Mes is 2,4,6-trimethylphenyl:

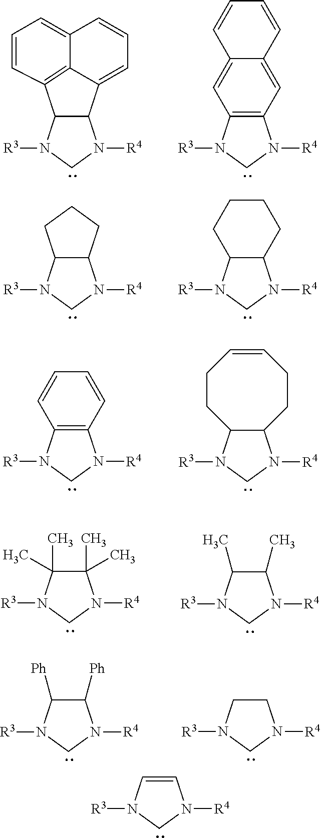

Additional examples of N-heterocyclic carbene (NHC) ligands and acyclic diaminocarbene ligands suitable as L¹ thus include, but are not limited to the following:

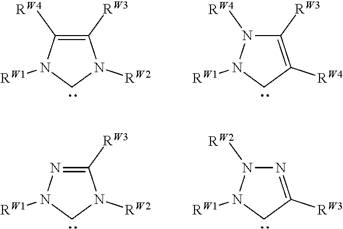

wherein R^{W1}, R^{W2}, R^{W3}, R^{W4} are independently hydrogen, unsubstituted hydrocarbyl, substituted hydrocarbyl, or heteroatom containing hydrocarbyl, and where one or both of R^{W3} and R^{W4} may be in independently selected from halogen, nitro, amido, carboxyl, alkoxy, aryloxy, sulfonyl, carbonyl, thio, or nitroso groups.

Additional examples of suitable N-heterocyclic carbene (NHC) ligands are further described in U.S. Pat. Nos. 7,378,528; 7,652,145; 7,294,717; 6,787,620; 6,635,768; and 6,552,139 the contents of each are incorporated herein by reference.

In a more preferred embodiment, Q is a two-atom linkage having the structure —CR¹¹R¹²—CR¹³R¹⁴— or —CR¹¹═CR¹³—, preferably —CR¹¹R¹²—CR¹³R¹⁴—, wherein R¹¹, R¹², R¹³, and R¹⁴ are independently selected from hydrogen, hydrocarbyl, substituted hydrocarbyl, heteroatom-containing hydrocarbyl, substituted heteroatom-containing hydrocarbyl, and functional groups. Examples of functional groups here include without limitation carboxyl, C₁-C₂₀ alkoxy, C₅-C₂₄ aryloxy, C₂-C₂₀ alkoxycarbonyl, C₅-C₂₄ alkoxycarbonyl, C₂-C₂₄ acyloxy, C₁-C₂₀ alkylthio, C₅-C₂₄ arylthio, C₁-C₂₀ alkylsulfonyl, and C₁-C₂₀ alkylsulfinyl, optionally substituted with one or more moieties selected from C₁-C₁₂ alkyl, C₁-C₁₂ alkoxy, C₅-C₁₄ aryl, hydroxyl, sulfhydryl, formyl, and halide. R¹¹, R¹², R¹³, and R¹⁴ are preferably independently selected from hydrogen, C₁-C₁₂ alkyl, substituted C₁-C₁₂ alkyl, C₁-C₁₂ heteroalkyl, substituted C₁-C₁₂ heteroalkyl, phenyl, and substituted phenyl. Alternatively, any two of R¹¹, R¹², R¹³, and R¹⁴ may be linked together to form a substituted or unsubstituted, saturated or unsaturated ring structure, e.g., a C₄-C₁₂ alicyclic group or a C₅ or C₆ aryl group, which may itself be substituted, e.g., with linked or fused alicyclic or aromatic groups, or with other substituents. In one further aspect, any one or more of R¹¹, R¹², R¹³, and R¹⁴ comprises one or more of the linkers. Additionally, R³ and R⁴ may be unsubstituted phenyl or phenyl substituted with one or more substituents selected from C₁-C₂₀ alkyl, substituted C₁-C₂₀ alkyl, C₁-C₂₀ heteroalkyl, substituted C₁-C₂₀ heteroalkyl, C₅-C₂₄ aryl, substituted C₅-C₂₄ aryl, C₅-C₂₄ heteroaryl, C₆-C₂₄ aralkyl, C₆-C₂₄ alkaryl, or halide. Furthermore, X¹ and X² may be halogen.

When R³ and R⁴ are aromatic, they are typically although not necessarily composed of one or two aromatic rings, which may or may not be substituted, e.g., R³ and R⁴ may be phenyl, substituted phenyl, biphenyl, substituted biphenyl, or the like. In one preferred embodiment, R³ and R⁴ are the same and are each unsubstituted phenyl or phenyl substituted with up to three substituents selected from C₁-C₂₀ alkyl, substituted C₁-C₂₀ alkyl, C₁-C₂₀ heteroalkyl, substituted C₁-C₂₀ heteroalkyl, C₅-C₂₄ aryl, substituted C₅-C₂₄ aryl, C₅-C₂₄ heteroaryl, C₆-C₂₄ aralkyl, C₆-C₂₄ alkaryl, or halide. Preferably, any substituents present are hydrogen, C₁-C₁₂ alkyl, C₁-C₁₂ alkoxy, C₅-C₁₄ aryl, substituted C₅-C₁₄ aryl, or halide. As an example, R³ and R⁴ are mesityl (i.e. Mes as defined herein).

In some preferred embodiments, Q may be defined as having the structure —CH₂—CH₂— and either R³ or R⁴, or both R³ and R⁴ are phenyl groups, optionally substituted in the 2, 4, 6 positions with independent C₁₋₆ alkyl groups, where C₃₋₆ alkyl groups may be branched or linear, e.g., including methyl, ethyl, n-propyl, iso-propyl, n-butyl, sec-butyl, tert-butyl. In certain preferred embodiments, the phenyl groups are optionally substituted in the 2, 6 positions with independent C₁₋₆ alkyl groups, and the 4-position is optionally substituted with an electron-withdrawing or -donating group as described herein, for example, alkyl, alkoxy, nitro, or halo. In other embodiments, Q is —CH₂—CH₂— and R³ and R⁴ are independently mesityl or optionally substituted adamantyl.

The bipyridine substituents, R⁵ and R⁶ are described as independently H or electron-withdrawing or electron-donating groups, including C₁₋₂₄alkyl, C₁₋₂₄alkoxy, C₁₋₂₄fluoroalkyl, C₁₋₂₄fluoroalkoxy, C₁₋₂₄alkylhydroxy, C₁₋₂₄alkoxyhydroxy, C₁₋₂₄fluoroalkylhydroxy(including perfluoroalkylhydroxy), C₁₋₂₄fluoroalkoxyhydroxy, halo, cyano, nitro, or hydroxy; and m and n are described as independently 1, 2, 3, or 4. The electron-withdrawing groups (EWG) or electron-donating groups (EDG) may more broadly include, independently at each occurrence, —NH₂, —NHR, —NR₂ (where R is C₁₋₁₈ alkyl), hydroxide, C₁₋₁₈ alkoxide, —NHC(O)(C₁₋₁₈ alkyl), C₁₋₁₈ alkyl, C₆₋₁₀ aryl, nitro, quaternary amines, halo- or perhalo-C₁₋₁₈ alkyl, —CN, —C₀₋₆ alkylsulfonate, —C₀₋₆ alkyl phosphonate, —C₁₋₆ alkyl-C(O)—R (where R is C₁₋₁₈ alkyl), or —C₁₋₆alkoxycarbonyls. In preferred embodiments, the EWG or EDG include, independently at each occurrence —NH₂, —NHR, —NR₂ (where R is C₁₋₃ alkyl), hydroxide, C₁₋₃ alkoxide, —NHC(O)(C₁₋₃ alkyl), C₁₋₆ alkyl, C₆aryl, nitro, quaternary amines, CF₃, —CN, —C₁₋₆ alkylsulfonate, —C₀₋₃ alkyl phosphonate, -carboxylate, or —C₁₋₃alkoxycarbonyl, silyl, or phosphonyl.

In preferred embodiments, R⁵ and R⁶ are independently H, methyl, ethyl, propyl, butyl, methoxy, trifluoromethyl, fluoro, chloro, bromo, cyano, or nitro.

Each R⁵ and R⁶ may be independently positioned one their ring, though typically they are positioned on the corresponding positions. That is, one or more of R⁵ may be present in any one or more of the 3, 4, 5, or 6 positions, and R⁶ may be independently present in any one or more of the 3′, 4′, 5′, or 6′ positions. But in preferred embodiments, the optionally substituted 2,2′-bipyridine is substituted with R⁵ and R⁶ in the 3,3′ or 4,4′ or 5,5′ or 6,6′ positions, most preferably in the 4,4′ or 5,5′ positions:

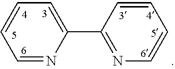 [SMILES: c1ccc(-c2ccccn2)nc1]

A ruthenium catalyst having a structure of Formula (1A) has been found to be especially useful in the disclosed compositions and methods:

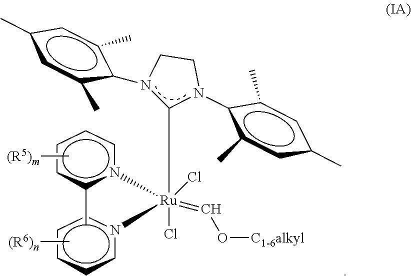

These ruthenium-bipyridine catalysts may be provided to the compositions as shown, or may be generated in situ by the mixing of an optionally substituted 2,2′-bipyridine, a quenching agent of

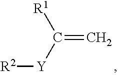

and a metathesis catalyst of Formula (IIA), (IIB), (IIIA), or (IIIB); or a geometric isomer thereof:

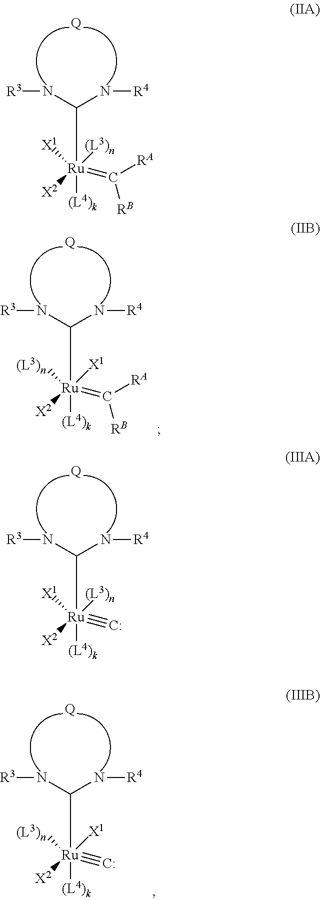

wherein:

L³ and L⁴ are independently neutral electron donor ligands;

k and n are independently 0 or 1; and

R^{A}, and R^{B} are independently hydrogen or optionally substituted hydrocarbyl, or may be linked to form an optionally substituted aromatic or aliphatic cyclic group,

where Q, X¹, X², R³, and R⁴ are as described elsewhere herein.

Such structures include:

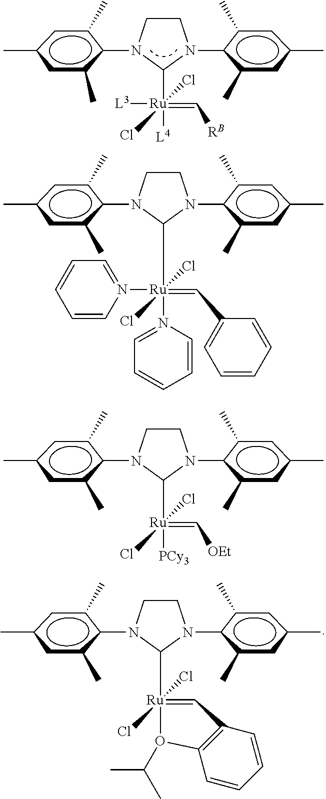

Throughout this specification, words are to be afforded their normal meaning, as would be understood by those skilled in the relevant art. However, so as to avoid misunderstanding, the meanings of certain terms will be specifically defined or clarified.

The term “anionic ligands” refer to those ligands coordinated to a metal cental, which are more electronegative than the metal to an extent that they are typically considered to carry a negative charge. Alternatively, if not coordinated to a metal center as a ligand, they would be anions. Such ligands, for example, include chloride, bromide, nitrate, sulfate, etc.

Where a given catalyst structure is provided, that structure is considered a specific embodiment. However, it should be appreciated that catalytic cycles by their nature involve transient intermediates or compounds which are transformed during the course of their reaction. As such, the term catalyst, when applied to a given structure, should also be considered to include those transient structures associated with the catalytic cycles of the provided structures. Additionally, the actual structure may be a geometric isomer of that actually shown. Geometric isomers are two or more coordination compounds which contain the same number and types of atoms, and bonds (i.e., the connectivity between atoms is the same), but which have different spatial arrangements of the atoms around the metal center. The isomer in which like ligands are adjacent to one another is called the cis isomer.

By “substituted” as in “substituted hydrocarbyl,” “substituted alkyl,” “substituted aryl,” and the like, as alluded to in some of the aforementioned definitions, is meant that in the hydrocarbyl, alkyl, aryl, heteroaryl, or other moiety, at least one hydrogen atom bound to a carbon (or other) atom is replaced with one or more non-hydrogen substituents. Examples of such substituents include, without limitation: functional groups referred to herein as “Fn,” such as halo (e.g., F, Cl, Br, I), hydroxyl, sulfhydryl, C₁-C₂₄ alkoxy, C₂-C₂₄ alkenyloxy, C₂-C₂₄ alkynyloxy, C₅-C₂₄ aryloxy, C₆-C₂₄ aralkyloxy, C₆-C₂₄ alkaryloxy, acyl (including C₁-C₂₄ alkylcarbonyl (—CO-alkyl) and C₆-C₂₄ arylcarbonyl (—CO-aryl)), acyloxy (—O-acyl, including C₂-C₂₄ alkylcarbonyloxy (—O—CO— alkyl) and C₆-C₂₄ arylcarbonyloxy (—O—CO-aryl)), C₂-C₂₄ alkoxycarbonyl ((CO)—O-alkyl), C₆-C₂₄ aryloxycarbonyl (—(CO)—O-aryl), halocarbonyl (—CO)—X where X is halo), C₂-C₂₄ alkylcarbonato (—O—(CO)—O-alkyl), C₆-C₂₄ arylcarbonato (—O—(CO)—O-aryl), carboxy (—COOH), carboxylato (—COO—), carbamoyl (—(CO)—NH₂), mono-(C₁-C₂₄ alkyl)-substituted carbamoyl (—(CO)NH(C₁-C₂₄ alkyl)), di-(C₁-C₂₄ alkyl)-substituted carbamoyl (—(CO)—N(C₁-C₂₄ alkyl)₂), mono-(C₁-C₂₄ haloalkyl)-substituted carbamoyl (—(CO)—NH(C₁-C₂₄ alkyl)), di-(C₁-C₂₄ haloalkyl)-substituted carbamoyl (—(CO)—N(C₁-C₂₄ alkyl)₂), mono-(C₅-C₂₄ aryl)-substituted carbamoyl (—(CO)—NH-aryl), di-(C₅-C₂₄ aryl)substituted carbamoyl (—(CO)—N(C₅-C₂₄ aryl)₂), di-N—(C₁-C₂₄ alkyl),N—(C₅-C₂₄ aryl)-substituted carbamoyl, thiocarbamoyl (—(CS)—NH₂), mono-(C₁-C₂₄ alkyl)-substituted thiocarbamoyl (—(CO)—NH(C₁-C₂₄ alkyl)), di-(C₁-C₂₄ alkyl)-substituted thiocarbamoyl (—(CO)—N(C₁-C₂₄ alkyl)₂), mono-(C₅-C₂₄ aryl)substituted thiocarbamoyl (—(CO)—NH-aryl), di-(C₅-C₂₄ aryl)-substituted thiocarbamoyl (—(CO)—N(C₅-C₂₄ aryl)₂), di-N—(C₁-C₂₄ alkyl),N—(C₅-C₂₄ aryl)-substituted thiocarbamoyl, carbamido (—NH—(CO)—NH₂), cyano(-C═N), cyanato (—O—C═N), thiocyanato (—S—C═N), formyl (—(CO)—H), thioformyl (—(CS)—H), amino (—NH₂), mono-(C₁-C₂₄ alkyl)-substituted amino, di-(C₁-C₂₄ alkyl)-substituted amino, mono-(C₅-C₂₄ aryl)substituted amino, di-(C₅-C₂₄ aryl)-substituted amino, C₁-C₂₄ alkylamido (—NH—(CO)-alkyl), C₆-C₂₄ arylamido (—NH—(CO)-aryl), imino (—CR═NH where R=hydrogen, C₁-C₂₄ alkyl, C₅-C₂₄ aryl, C₆-C₂₄ alkaryl, C₆-C₂₄ aralkyl, etc.), C₂-C₂₀ alkylimino (—CR═N(alkyl), where R=hydrogen, C₁-C₂₄ alkyl, C₅-C₂₄ aryl, C₆-C₂₄ alkaryl, C₆-C₂₄ aralkyl, etc.), arylimino (—CR═N(aryl), where R=hydrogen, C₁-C₂₀ alkyl, C₅-C₂₄ aryl, C₆-C₂₄ alkaryl, C₆-C₂₄ aralkyl, etc.), nitro (—NO₂), nitroso (—NO), sulfo (—SO₂OH), sulfonate(SO₂O—), C₁-C₂₄ alkylsulfanyl (—S-alkyl; also termed “alkylthio”), C₅-C₂₄ arylsulfanyl (—S-aryl; also termed “arylthio”), C₁-C₂₄ alkylsulfinyl (—(SO)-alkyl), C₅-C₂₄ arylsulfinyl (—(SO)-aryl), C₁-C₂₄ alkylsulfonyl (—SO₂-alkyl), C₁-C₂₄ monoalkylaminosulfonyl-SO₂—N(H) alkyl), C₁-C₂₄ dialkylaminosulfonyl-SO₂—N(alkyl)₂, C₅-C₂₄ arylsulfonyl (—SO₂-aryl), boryl (—BH₂), borono (—B(OH)₂), boronato (—B(OR)₂ where R is alkyl or other hydrocarbyl), phosphono (—P(O)(OH)₂), phosphonato (—P(O)(O)₂), phosphinato (P(O)(O—)), phospho (—PO₂), and phosphine (—PH₂); and the hydrocarbyl moieties C₁-C₂₄ alkyl (preferably C₁-C₁₂ alkyl, more preferably C₁-C₆ alkyl), C₂-C₂₄ alkenyl (preferably C₂-C₁₂ alkenyl, more preferably C₂-C₆ alkenyl), C₂-C₂₄ alkynyl (preferably C₂-C₁₂ alkynyl, more preferably C₂-C₆ alkynyl), C₅-C₂₄ aryl (preferably C₅-C₂₄ aryl), C₆-C₂₄ alkaryl (preferably C₆-C₁₆ alkaryl), and C₆-C₂₄ aralkyl (preferably C₆-C₁₆ aralkyl). Within these substituent structures, the “alkyl,” “alkylene,” “alkenyl,” “alkenylene,” “alkynyl,” “alkynylene,” “alkoxy,” “aromatic,” “aryl,” “aryloxy,” “alkaryl,” and “aralkyl” moieties may be optionally fluorinated or perfluorinated. Additionally, reference to alcohols, aldehydes, amines, carboxylic acids, ketones, or other similarly reactive functional groups also includes their protected analogs. For example, reference to hydroxy or alcohol also includes those substituents wherein the hydroxy is protected by acetyl (Ac), benzoyl (Bz), benzyl (Bn, Bnl), β-Methoxyethoxymethyl ether (MEM), dimethoxytrityl, [bis-(4-methoxyphenyl)phenylmethyl] (DMT), methoxymethyl ether (MOM), methoxytrityl [(4-methoxyphenyl)diphenylmethyl, MMT), p-methoxybenzyl ether (PMB), methylthiomethyl ether, pivaloyl (Piv), tetrahydropyranyl (THP), tetrahydrofuran (THF), trityl (triphenylmethyl, Tr), silyl ether (most popular ones include trimethylsilyl (TMS), tert-butyldimethylsilyl (TBDMS), tri-iso-propylsilyloxymethyl (TOM), and triisopropylsilyl (TIPS) ethers), ethoxyethyl ethers (EE). Reference to amines also includes those substituents wherein the amine is protected by a BOC glycine, carbobenzyloxy (Cbz), p-methoxybenzyl carbonyl (Moz or MeOZ), tert-butyloxycarbonyl (BOC), 9-fluorenylmethyloxycarbonyl (FMOC), acetyl (Ac), benzoyl (Bz), benzyl (Bn), carbamate, p-methoxybenzyl (PMB), 3,4-dimethoxybenzyl (DMPM), p-methoxyphenyl (PMP), tosyl (Ts) group, or sulfonamide (Nosyl & Nps) group. Reference to substituent containing a carbonyl group also includes those substituents wherein the carbonyl is protected by an acetal or ketal, acylal, or diathane group. Reference to substituent containing a carboxylic acid or carboxylate group also includes those substituents wherein the carboxylic acid or carboxylate group is protected by its methyl ester, benzyl ester, tert-butyl ester, an ester of 2,6-disubstituted phenol (e.g. 2,6-dimethylphenol, 2,6-diisopropylphenol, 2,6-di-tert-butylphenol), a silyl ester, an orthoester, or an oxazoline.

By “functionalized” as in “functionalized hydrocarbyl,” “functionalized alkyl,” “functionalized olefin,” “functionalized cyclic olefin,” and the like, is meant that in the hydrocarbyl, alkyl, aryl, heteroaryl, olefin, cyclic olefin, or other moiety, at least one hydrogen atom bound to a carbon (or other) atom is replaced with one or more functional groups such as those described herein and above. The term “functional group” is meant to include any functional species that is suitable for the uses described herein. In particular, as used herein, a functional group would necessarily possess the ability to react with or bond to corresponding functional groups on a substrate surface.

“Optional” or “optionally” means that the subsequently described circumstance may or may not occur, so that the description includes instances where the circumstance occurs and instances where it does not. For example, the phrase “optionally substituted” means that a non-hydrogen substituent may or may not be present on a given atom, and, thus, the description includes structures wherein a non-hydrogen substituent is present and structures wherein a non-hydrogen substituent is not present.

In some embodiments, L⁴ is phosphine, sulfonated phosphine, phosphite, phosphinite, phosphonite, arsine, stibine, ether, (including cyclic ethers), amine, amide, imine, sulfoxide, carboxyl, nitrosyl, pyridine, substituted pyridine, imidazole, substituted imidazole, pyrazine, substituted pyrazine or thioether. Exemplary ligands are trisubstituted phosphines. Preferred trisubstituted phosphines are of the formula PR^{H1}R^{H2}R^{H3}, where R^{H1}, R^{H2}, and R^{H3} are each independently substituted or unsubstituted aryl or C₁-C₁₀ alkyl, particularly primary alkyl, secondary alkyl, or cycloalkyl. In other embodiments L⁴ is trimethylphosphine (PMe₃), triethylphosphine (PEt₃), tri-n-butylphosphine (PBu₃), tri(ortho-tolyl)phosphine (P-o-tolyl₃), tri-tert-butylphosphine (P-tert-Bu₃), tricyclopentylphosphine (PCyclopentyl₃), tricyclohexylphosphine (PCy₃), triisopropylphosphine (P-i-Pr₃), trioctylphosphine (POct₃), triisobutylphosphine, (P-i-Bu₃), triphenylphosphine (PPh₃), tri(pentafluorophenyl)phosphine (P(C₆F₅)₃), methyldiphenylphosphine (PMePh₂), dimethylphenylphosphine (PMe₂Ph), or diethylphenylphosphine (PEt₂Ph).

In other embodiments, L³ and L⁴ include, without limitation, heterocycles containing nitrogen, sulfur, oxygen, or a mixture thereof.

Examples of nitrogen-containing heterocycles appropriate for L³ and L⁴ include pyridine, bipyridine, pyridazine, pyrimidine, bipyridamine, pyrazine, 1,3,5-triazine, 1,2,4-triazine, 1,2,3-triazine, pyrrole, 2H-pyrrole, 3H-pyrrole, pyrazole, 2H-imidazole, 1,2,3-triazole, 1,2,4-triazole, indole, 3H-indole, 1H-isoindole, cyclopenta(b)pyridine, indazole, quinoline, bisquinoline, isoquinoline, bisisoquinoline, cinnoline, quinazoline, naphthyridine, piperidine, piperazine, pyrrolidine, pyrazolidine, quinuclidine, imidazolidine, picolylimine, purine, benzimidazole, bisimidazole, phenazine, acridine, and carbazole. Additionally, the nitrogen-containing heterocycles may be optionally substituted on a non-coordinating heteroatom with a non-hydrogen substitutent.

Examples of sulfur-containing heterocycles appropriate for L³ and L⁴ include thiophene, 1,2-dithiole, 1,3-dithiole, thiepin, benzo(b)thiophene, benzo(c)thiophene, thionaphthene, dibenzothiophene, 2H-thiopyran, 4H-thiopyran, and thioanthrene.

Examples of oxygen-containing heterocycles appropriate for L³ and L⁴ include 2H-pyran, 4H-pyran, 2-pyrone, 4-pyrone, 1,2-dioxin, 1,3-dioxin, oxepin, furan, 2H-1-benzopyran, coumarin, coumarone, chromene, chroman-4-one, isochromen-1-one, isochromen-3-one, xanthene, tetrahydrofuran, 1,4-dioxan, and dibenzofuran.

Examples of mixed heterocycles appropriate for L³ and L⁴ include isoxazole, oxazole, thiazole, isothiazole, 1,2,3-oxadiazole, 1,2,4-oxadiazole, 1,3,4-oxadiazole, 1,2,3,4-oxatriazole, 1,2,3,5-oxatriazole, 3H-1,2,3-dioxazole, 3H-1,2-oxathiole, 1,3-oxathiole, 4H-1,2-oxazine, 2H-1,3-oxazine, 1,4-oxazine, 1,2,5-oxathiazine, o-isooxazine, phenoxazine, phenothiazine, pyrano[3,4-b]pyrrole, indoxazine, benzoxazole, anthranil, and morpholine.

Preferred L³ and L⁴ ligands are aromatic nitrogen-containing and oxygen-containing heterocycles, and particularly preferred L³ and L⁴ ligands are monocyclic N-heteroaryl ligands that are optionally substituted with 1 to 3, preferably 1 or 2, substituents. Specific examples of particularly preferred L³ and L⁴ ligands are pyridine and substituted pyridines, such as 3-bromopyridine, 4-bromopyridine, 3,5-dibromopyridine, 2,4,6-tribromopyridine, 2,6-dibromopyridine, 3-chloropyridine, 4-chloropyridine, 3,5-dichloropyridine, 2,4,6-trichloropyridine, 2,6-dichloropyridine, 4-iodopyridine, 3,5-diiodopyridine, 3,5-dibromo-4-methylpyridine, 3,5-dichloro-4-methylpyridine, 3,5-dimethyl-4-bromopyridine, 3,5-dimethylpyridine, 4-methylpyridine, 3,5-diisopropylpyridine, 2,4,6-trimethylpyridine, 2,4,6-triisopropylpyridine, 4-(tert-butyl)pyridine, 4-phenylpyridine, 3,5-diphenylpyridine, 3,5-dichloro-4-phenylpyridine, and the like.

Photochemical Conditions

As used herein, and unless otherwise stated, the term “activates” refers to the fact that the irradiated catalyst metathesizes (i.e., polymerizes or crosslinks) olefins or alkynes at a rate that is faster at least 10 times faster than metathesizes the same olefins or alkynes before irradiation. Having said this, and when so specified, independent embodiments provide that the irradiated catalyst metathesizes olefins or alkynes at a rate that is faster at least 2 times, 5 times, 50 times, 100 times, or 1000 times faster than the metathesis of the same olefins or alkynes before or without irradiation.

The present ruthenium-bipyridine catalysts allow for the use of simple LED sources, which illuminate at a single wavelength and at lower energies, in contrast to Hg lamps typically used in mask aligners. These bipyridine coordination complexes show reactivity at one or more wavelengths in a range of from about 250 to about 800 nm, from about 300 to about 500 nm, or in a range of from about 340 to about 460 nm, preferably in a range of from about 380 to about 420 nm. Additional embodiments provide that the light comprises at least one wavelength in a range of from about 250 to about 300 nm, from about 300 to about 320 nm, from about 320 to about 340 nm, from about 340 to about 360 nm, from about 360 to about 380 nm, from about 380 to about 400 nm, from about 400 to about 420 nm, from about 420 to about 440 nm, from about 440 to about 460 nm, from about 460 to about 480 nm, from about 480 to about 500 nm, from about 500 to about 600 nm, from about 600 to about 700 nm, from about 700 to about 800 nm, or a combination thereof. This is consistent with currently available dry-polymer photopolymers used in the printed circuit industry (e.g. photoresist and solder mask) function when exposed to ultraviolet (UV) radiation in the range of about 300 nm to about 440 nm in a production environment.

Additional embodiments provide that the compositions may be activated by two- or three-photon energy sources, for example, using a focused 790 nm laser to provide three-dimensional structures written using this multi-photon absorption. Other multi-photon lithography methods may also be employed, including interference lithography techniques such as phase mask lithography and proximity field nanopatterning. Other patterning strategies, including nanoimprint lithography, substrate conformal imprint lithography, stimulated emission and depletion lithography, are also methods which can be used in concert with the present compositions and methods.

In particular, nanoimprint lithography is a technique that is widely used to replicate nanostructured layers. This technique has the advantage that the imprinting stamp can be reused many times. The time-intensive process of making a ‘master’ for the stamp need only be performed once, enabling rapid duplication applicable to industrial scale micro- and nanofabrication. This method has been shown to be applicable with the present methods and compositions, thereby enabling the rapid and large-area fabrication of chemically functional nanostructures.

Similarly, these Fischer-type carbene ruthenium metathesis catalysts become activated after being irradiated with a light having an intensity in a range of 1 mW/cm² to 10 W/cm², preferably about 10 mW/cm² to 200 mW/cm², at one or more wavelength in one of the ranges described above, for example in a range of about 220 to 440 nm. For some systems, depending on the reactivity of the specific catalyst and/or olefins, the energy of sunlight is sufficient to activate these materials. It is expected that the catalysts described herein will work at these levels, if necessary to go there.

Unsaturated Precursors

The methods of the present disclosure also consider that the Fischer-type carbene ruthenium metathesis catalyst as described herein, may be dissolved in a solvent in the presence of at least one unsaturated organic precursor or are admixed or dissolved in at least one unsaturated organic precursor. As used herein, the term “at least one unsaturated organic precursor” is intended to connote one or more molecular compound or oligomer, or combination thereof, each comprising at least one olefinic (alkene) or one acetylenic (alkyne) bond per molecule or oligomeric unit. These precursors comprise cyclic or alicyclic cis- or trans-olefins or cyclic or alicyclic acetylenes, or a structure having both types of bonds (including alicyclic or cyclic enynes).

The photosensitive, polymerizable compositions may also be described as being dissolved or admixed within polymerizable material matrix. Such matrices include those comprising polymers, polymer precursors, or a combination thereof, provided that the matrix contains at least one olefinic (alkene) or one acetylenic (alkyne) bond per molecule, oligomeric unit, or polymeric unit. Such compositions may include crosslinking polymers. In some cases, the mixture of polymerized and non-polymerized materials may result from the incomplete polymerization of the polymer precursor. In other cases, the polymerized and non-polymerized materials may be chemically unrelated.

The inventive compositions and methods may also comprise alkynyl precursors. As used herein, the term “alkynyl” (or “acetylenic”) or “alkyne” refers to a linear or branched hydrocarbon group or compound of 2 to about 24 carbon atoms containing at least one triple bond, such as ethynyl, n-propynyl, and the like. Preferred alkynyl groups herein contain 2 to about 12 carbon atoms, preferably containing a terminal alkyne bond. The term “lower alkynyl” refers to an alkynyl group of 2 to 6 carbon atoms. The term “substituted alkynyl” refers to alkynyl substituted with one or more substituent groups. As used herein, the terms “optional” or “optionally” mean that the subsequently described circumstance may or may not occur, so that the description includes instances where the circumstance occurs and instances where it does not. For example, the phrase “optionally substituted” means that a non-hydrogen substituent may or may not be present on a given atom, and, thus, the description includes structures wherein a non-hydrogen substituent is present and structures wherein a non-hydrogen substituent is not present.

Olefinic precursors may be used in tandem with the alkynes, either employed as part of the feedstock mixtures, or in sequential processing of the product polymers. Suitable options for such precursors are those ring systems, particularly strained ring systems, which are useful for ROMP reactions. One such class of compounds in this regard is substituted or unsubstituted cyclooctatetraenes, including cyclooctatetraene itself.

As described above, suitable options for such olefinic or acetylenic precursors include ring systems, particularly strained ring systems, which are useful for ROMP reactions. Such cyclic olefins may be optionally substituted, optionally heteroatom-containing, mono-unsaturated, di-unsaturated, or poly-unsaturated C₅ to C₂₄ hydrocarbons that may be mono-, di-, or poly-cyclic. The cyclic olefin may generally be any strained or unstrained cyclic olefin, provided the cyclic olefin is able to participate in a ROMP reaction either individually or as part of a ROMP cyclic olefin composition. While certain unstrained cyclic olefins such as cyclohexene are generally understood to not undergo ROMP reactions by themselves, under appropriate circumstances, such unstrained cyclic olefins may nonetheless be ROMP active. For example, when present as a co-monomer in a ROMP composition, unstrained cyclic olefins may be ROMP active. Accordingly, as used herein and as would be appreciated by the skilled artisan, the term “unstrained cyclic olefin” is intended to refer to those unstrained cyclic olefins that may undergo a ROMP reaction under any conditions, or in any ROMP composition, provided the unstrained cyclic olefin is ROMP active.

In general, the cyclic olefin may be represented by the structure of formula (A)

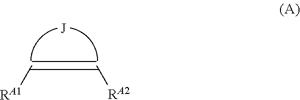

wherein J, R^{A1}, and R^{A2} are as follows:

R^{A1} and R^{A2} is selected independently from the group consisting of hydrogen, hydrocarbyl (e.g., C₁-C₂₀ alkyl, C₅-C₂₀ aryl, C₅-C₃₀ aralkyl, or C₅-C₃₀ alkaryl), substituted hydrocarbyl (e.g., substituted C₁-C₂₀ alkyl, C₅-C₂₀ aryl, C₅-C₃₀ aralkyl, or C₅-C₃₀ alkaryl), heteroatom-containing hydrocarbyl (e.g., C₁-C₂₀ heteroalkyl, C₅-C₂₀ heteroaryl, heteroatom-containing C₅-C₃₀ aralkyl, or heteroatom-containing C₅-C₃₀ alkaryl), and substituted heteroatom-containing hydrocarbyl (e.g., substituted C₁-C₂₀ heteroalkyl, C₅-C₂₀ heteroaryl, heteroatom-containing C₅-C₃₀ aralkyl, or heteroatom-containing C₅-C₃₀ alkaryl) and, if substituted hydrocarbyl or substituted heteroatom-containing hydrocarbyl, wherein the substituents may be functional groups (“Fn”) such as alkene, alkyne, phosphonato, phosphoryl, phosphanyl, phosphino, sulfonato, C₁-C₂₀ alkylsulfanyl, C₅-C₂₀ arylsulfanyl, C₁-C₂₀ alkylsulfonyl, C₅-C₂₀ arylsulfonyl, C₁-C₂₀ alkylsulfinyl, C₅-C₂₀ arylsulfinyl, sulfonamido, amino, amido, imino, nitro, nitroso, hydroxyl, C₁-C₂₀ alkoxy, C₅-C₂₀ aryloxy, C₂-C₂₀ alkoxycarbonyl, C₅-C₂₀ aryloxycarbonyl, carboxyl, carboxylato, mercapto, formyl, C₁-C₂₀ thioester, cyano, cyanato, thiocyanato, isocyanate, thioisocyanate, carbamoyl, epoxy, styrenyl, silyl, silyloxy, silanyl, siloxazanyl, boronato, boryl, or halogen, or a metal-containing or metalloid-containing group (wherein the metal may be, for example, Sn or Ge). R^{A1} and R^{A2} may itself be one of the aforementioned groups, such that the Fn moiety is directly bound to the olefinic carbon atom indicated in the structure. In the latter case, however, the functional group will generally not be directly bound to the olefinic carbon through a heteroatom containing one or more lone pairs of electrons, e.g., an oxygen, sulfur, nitrogen, or phosphorus atom, or through an electron-rich metal or metalloid such as Ge, Sn, As, Sb, Se, Te, etc. With such functional groups, there will normally be an intervening linkage Z*, such that R^{A1} and/or R^{A2} then has the structure —(Z*)ₙ-Fn wherein n is 1, Fn is the functional group, and Z* is a hydrocarbylene linking group such as an alkylene, substituted alkylene, heteroalkylene, substituted heteroalkene, arylene, substituted arylene, heteroarylene, or substituted heteroarylene linkage.

J is a saturated or unsaturated hydrocarbylene, substituted hydrocarbylene, heteroatom-containing hydrocarbylene, or substituted heteroatom-containing hydrocarbylene linkage, wherein when J is substituted hydrocarbylene or substituted heteroatom-containing hydrocarbylene, the substituents may include one or more —(Z*)ₙ-Fn groups, wherein n is zero or 1, and Fn and Z* are as defined previously. Additionally, two or more substituents attached to ring carbon (or other) atoms within J may be linked to form a bicyclic or polycyclic olefin. J will generally contain in the range of approximately 5 to 14 ring atoms, typically 5 to 8 ring atoms, for a monocyclic olefin, and, for bicyclic and polycyclic olefins, each ring will generally contain 4 to 8, typically 5 to 7, ring atoms.

Mono-unsaturated cyclic olefins encompassed by structure (A) may be represented by the structure (B)

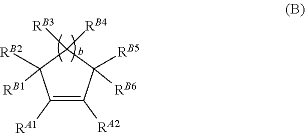

wherein b is an integer generally although not necessarily in the range of 1 to 10, typically 1 to 5,

R^{A1} and R^{A2} are as defined above for structure (A), and R^{B1}, R^{B2}, R^{B3}, R^{B4}, R^{B5}, and R^{B6} are independently selected from the group consisting of hydrogen, hydrocarbyl, substituted hydrocarbyl, heteroatom-containing hydrocarbyl, substituted heteroatom-containing hydrocarbyl and —(Z*)ₙ-Fn where n, Z* and Fn are as defined previously, and wherein if any of the R^{B1} through R^{B6} moieties is substituted hydrocarbyl or substituted heteroatom-containing hydrocarbyl, the substituents may include one or more —(Z*)ₙ-Fn groups. Accordingly, R^{B1}, R^{B2}, R^{B3}, R^{B4}, R^{B5}, and R^{B6} may be, for example, hydrogen, hydroxyl, C₁-C₂₀ alkyl, C₅-C₂₀ aryl, C₁-C₂₀ alkoxy, C₅-C₂₀ aryloxy, C₂-C₂₀ alkoxycarbonyl, C₅-C₂₀ aryloxycarbonyl, amino, amido, nitro, etc.

Furthermore, any of the R^{B1}, R^{B2}, R^{B3}, R^{B4}, R^{B5}, and R^{B6} moieties can be linked to any of the other R^{B1}, R^{B2}, R^{B3}, R^{B4}, R^{B5}, and R^{B6} moieties to provide a substituted or unsubstituted alicyclic group containing 4 to 30 ring carbon atoms or a substituted or unsubstituted aryl group containing 6 to 18 ring carbon atoms or combinations thereof and the linkage may include heteroatoms or functional groups, e.g. the linkage may include without limitation an ether, ester, thioether, amino, alkylamino, imino, or anhydride moiety. The alicyclic group can be monocyclic, bicyclic, or polycyclic. When unsaturated the cyclic group can contain monounsaturation or multiunsaturation, with monounsaturated cyclic groups being preferred. When substituted, the rings contain monosubstitution or multisubstitution wherein the substituents are independently selected from hydrogen, hydrocarbyl, substituted hydrocarbyl, heteroatom-containing hydrocarbyl, substituted heteroatom-containing hydrocarbyl, —(Z*)ₙ-Fn where n is zero or 1, Z* and Fn are as defined previously, and functional groups (Fn) provided above.

Examples of mono-unsaturated, monocyclic olefins encompassed by structure (B) include, without limitation, cyclopentene, cyclohexene, cycloheptene, cyclooctene, cyclononene, cyclodecene, cycloundecene, cyclododecene, tricyclodecene, tetracyclodecene, octacyclodecene, and cycloeicosene, and substituted versions thereof such as 1-methylcyclopentene, 1-ethylcyclopentene, 1-isopropylcyclohexene, 1-chloropentene, 1-fluorocyclopentene, 4-methylcyclopentene, 4-methoxy-cyclopentene, 4-ethoxy-cyclopentene, cyclopent-3-ene-thiol, cyclopent-3-ene, 4-methylsulfanyl-cyclopentene, 3-methylcyclohexene, 1-methylcyclooctene, 1,5-dimethylcyclooctene, etc.

Monocyclic diene reactants encompassed by structure (A) may be generally represented by the structure (C)

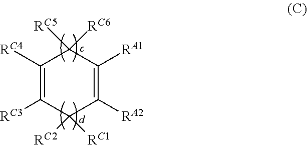

wherein c and d are independently integers in the range of 1 to about 8, typically 2 to 4, preferably 2 (such that the reactant is a cyclooctadiene), R^{A1} and R^{A2} are as defined above for structure (A), and R^{C1}, R^{C2}, R^{C3}, R^{C4}, R^{C5}, and R^{C6} are defined as for R^{B1} through R^{B6}. In this case, it is preferred that R^{C3} and R^{C4} be non-hydrogen substituents, in which case the second olefinic moiety is tetrasubstituted. Examples of monocyclic diene reactants include, without limitation, 1,3-cyclopentadiene, 1,3-cyclohexadiene, 1,4-cyclohexadiene, 5-ethyl-1,3-cyclohexadiene, 1,3-cycloheptadiene, cyclohexadiene, 1,5-cyclooctadiene, 1,3-cyclooctadiene, and substituted analogs thereof. Triene reactants are analogous to the diene structure (C), and will generally contain at least one methylene linkage between any two olefinic segments.
Bicyclic and polycyclic olefins encompassed by structure (A) may be generally represented by the structure (D)

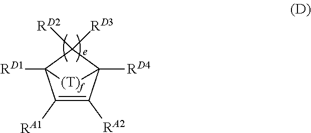

wherein R^{A1} and R^{A2} are as defined above for structure (A), R^{D1}, R^{D2}, R^{D3}, and R^{D4} are as defined for R^{B1} through R^{B6}, e is an integer in the range of 1 to 8 (typically 2 to 4) f is generally 1 or 2; T is lower alkylene or alkenylene (generally substituted or unsubstituted methyl or ethyl), CHR^{G1}, C(R^{G1})₂, O, S, N—R^{G1}, P—R^{G1}, O═P—R^{G1}, Si(R^{G1})₂, B—R^{G1}, or As—R^{G1} where R^{G1} is alkyl, alkenyl, cycloalkyl, cycloalkenyl, aryl, alkaryl, aralkyl, or alkoxy. Furthermore, any of the R^{D1}, R^{D2}, R^{D3}, and R^{D4} moieties can be linked to any of the other R^{D1}, R^{D2}, R^{D3}, and R^{D4} moieties to provide a substituted or unsubstituted alicyclic group containing 4 to 30 ring carbon atoms or a substituted or unsubstituted aryl group containing 6 to 18 ring carbon atoms or combinations thereof and the linkage may include heteroatoms or functional groups, e.g. the linkage may include without limitation an ether, ester, thioether, amino, alkylamino, imino, or anhydride moiety. The cyclic group can be monocyclic, bicyclic, or polycyclic. When unsaturated the cyclic group can contain mono-unsaturation or multi-unsaturation, with mono-unsaturated cyclic groups being preferred. When substituted, the rings contain mono-substitution or multi-substitution wherein the substituents are independently selected from hydrogen, hydrocarbyl, substituted hydrocarbyl, heteroatom-containing hydrocarbyl, substituted heteroatom-containing hydrocarbyl, —(Z*)ₙ-Fn where n is zero or 1, Z* and Fn are as defined previously, and functional groups (Fn) provided above.

Cyclic olefins encompassed by structure (D) are in the norbornene family. As used herein, norbornene means any compound that includes at least one norbornene or substituted norbornene moiety, including without limitation norbornene, substituted norbornene(s), norbomadiene, substituted norbomadiene(s), polycyclic norbornenes, and substituted polycyclic norbornene(s). Norbornenes within this group may be generally represented by the structure (E)

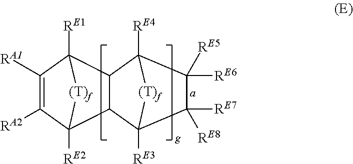

wherein R^{A1} and R^{A2} are as defined above for structure (A), T is as defined above for structure (D), R^{E1}, R^{E2}, R^{E3}, R^{E4}, R^{E5}, R^{E6}, R^{E7}, and R^{E8} are as defined for R^{B1} through R^{B6}, and “a” represents a single bond or a double bond, f is generally 1 or 2, “g” is an integer from 0 to 5, and when “a” is a double bond one of R^{E5}, R^{E6} and one of R^{E7}, R^{E8} is not present. Furthermore, any of the R^{E5}, R^{E6}, R^{E7}, and R^{E8} moieties can be linked to any of the other R^{E5}, R^{E6}, R^{E7}, and R^{E8} moieties to provide a substituted or unsubstituted alicyclic group containing 4 to 30 ring carbon atoms or a substituted or unsubstituted aryl group containing 6 to 18 ring carbon atoms or combinations thereof and the linkage may include heteroatoms or functional groups, e.g. the linkage may include without limitation an ether, ester, thioether, amino, alkylamino, imino, or anhydride moiety. The cyclic group can be monocyclic, bicyclic, or polycyclic. When unsaturated the cyclic group can contain monounsaturation or multiunsaturation, with monounsaturated cyclic groups being preferred. When substituted, the rings contain monosubstitution or multisubstitution wherein the substituents are independently selected from hydrogen, hydrocarbyl, substituted hydrocarbyl, heteroatom-containing hydrocarbyl, substituted heteroatom-containing hydrocarbyl, —(Z*)ₙ-Fn where n is zero or 1, Z* and Fn are as defined previously, and functional groups (Fn) provided above.

More preferred cyclic olefins possessing at least one norbornene moiety have the structure (F):

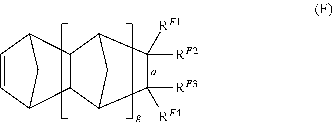

wherein, R^{F1}, R^{F2}, R^{F3}, and R^{F4}, are as defined for R^{B1} through R^{B6}, and “a” represents a single bond or a double bond, “g” is an integer from 0 to 5, and when “a” is a double bond one of R^{F1}, R^{F2} and one of R^{F3}, R^{F4} is not present.

Furthermore, any of the R^{F1}, R^{F2}, R³, and R^{F4} moieties can be linked to any of the other R^{F1}, R^{F2}, R³, and R^{F4} moieties to provide a substituted or unsubstituted alicyclic group containing 4 to 30 ring carbon atoms or a substituted or unsubstituted aryl group containing 6 to 18 ring carbon atoms or combinations thereof and the linkage may include heteroatoms or functional groups, e.g. the linkage may include without limitation an ether, ester, thioether, amino, alkylamino, imino, or anhydride moiety. The alicyclic group can be monocyclic, bicyclic, or polycyclic. When unsaturated the cyclic group can contain monounsaturation or multiunsaturation, with monounsaturated cyclic groups being preferred. When substituted, the rings contain monosubstitution or multisubstitution wherein the substituents are independently selected from hydrogen, hydrocarbyl, substituted hydrocarbyl, heteroatom-containing hydrocarbyl, substituted heteroatom-containing hydrocarbyl, —(Z*)ₙ-Fn where n is zero or 1, Z* and Fn are as defined previously, and functional groups (Fn) provided above.

One route for the preparation of hydrocarbyl substituted and functionally substituted norbornenes employs the Diels-Alder cycloaddition reaction in which cyclopentadiene or substituted cyclopentadiene is reacted with a suitable dienophile at elevated temperatures to form the substituted norbornene adduct generally shown by the following reaction Scheme 1:

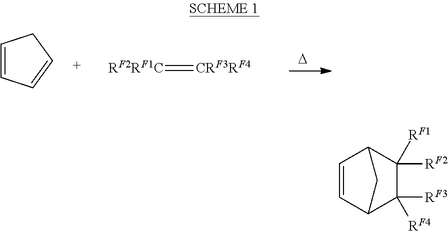

wherein R^{F1} to R^{F4} are as previously defined for structure (F).

Other norbornene adducts can be prepared by the thermal pyrolysis of dicyclopentadiene in the presence of a suitable dienophile. The reaction proceeds by the initial pyrolysis of dicyclopentadiene to cyclopentadiene followed by the Diels-Alder cycloaddition of cyclopentadiene and the dienophile to give the adduct shown below in Scheme 2:

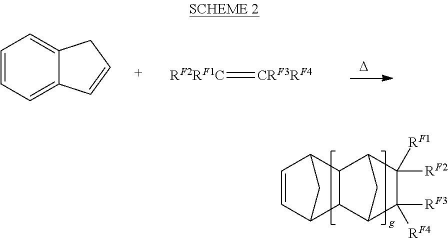

wherein “g” is an integer from 0 to 5, and R^{F1} to R^{F4} are as previously defined for structure (F).

Norbornadiene and higher Diels-Alder adducts thereof similarly can be prepared by the thermal reaction of cyclopentadiene and dicyclopentadiene in the presence of an acetylenic reactant as shown below in Scheme 3:

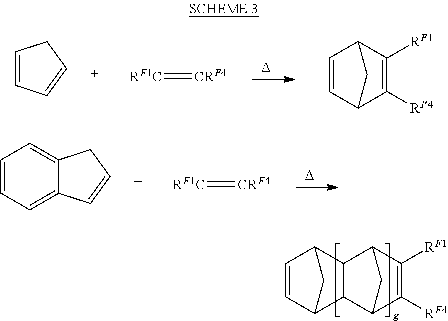

where in “g” is an integer from 0 to 5, R^{F1} and R^{F4} are as previously defined for structure (F) Examples of bicyclic and polycyclic olefins thus include, without limitation, dicyclopentadiene (DCPD); trimer and other higher order oligomers of cyclopentadiene including without limitation tricyclopentadiene (cyclopentadiene trimer), cyclopentadiene tetramer, and cyclopentadiene pentamer; ethylidenenorbornene; dicyclohexadiene; norbornene; 5-methyl-2-norbornene; 5-ethyl-2-norbornene; 5-isobutyl-2-norbornene; 5,6-dimethyl-2-norbornene; 5-phenylnorbornene; 5-benzylnorbornene; 5-acetylnorbornene; 5-methoxycarbonylnorbornene; 5-ethyoxycarbonyl-1-norbornene; 5-methyl-5-methoxy-carbonylnorbornene; 5-cyanonorbornene; 5,5,6-trimethyl-2-norbornene; cyclo-hexenylnorbornene; endo, exo-5,6-dimethoxynorbornene; endo, endo-5,6-dimethoxynorbornene; endo, exo-5,6-dimethoxycarbonylnorbornene; endo,endo-5,6-dimethoxycarbonylnorbornene; 2,3-dimethoxynorbornene; norbomadiene; tricycloundecene; tetracyclododecene; 8-methyltetracyclododecene; 8-ethyltetracyclododecene; 8-methoxycarbonyltetracyclododecene; 8-methyl-8-tetracyclododecene; 8-cyanotetracyclododecene; pentacyclopentadecene; pentacyclohexadecene; and the like, and their structural isomers, stereoisomers, and mixtures thereof. Additional examples of bicyclic and polycyclic olefins include, without limitation, C₂-C₁₂ hydrocarbyl substituted norbornenes such as 5-butyl-2-norbornene, 5-hexyl-2-norbornene, 5-octyl-2-norbornene, 5-decyl-2-norbornene, 5-dodecyl-2-norbornene, 5-vinyl-2-norbornene, 5-ethylidene-2-norbornene, 5-isopropenyl-2-norbornene, 5-propenyl-2-norbornene, and 5-butenyl-2-norbornene, and the like.

Preferred cyclic olefins include C₅ to C₂₄ unsaturated hydrocarbons. Also preferred are C₅ to C₂₄ cyclic hydrocarbons that contain one or more (typically 2 to 12) heteroatoms such as O, N, S, or P. For example, crown ether cyclic olefins may include numerous O heteroatoms throughout the cycle, and these are within the scope of the disclosure. In addition, preferred cyclic olefins are C₅ to C₂₄ hydrocarbons that contain one or more (typically 2 or 3) olefins. For example, the cyclic olefin may be mono-, di-, or tri-unsaturated. Examples of cyclic olefins include without limitation cyclooctene, cyclododecene, and (c,t,t)-1,5,9-cyclododecatriene.

The cyclic olefins may also comprise multiple (typically 2 or 3) rings. For example, the cyclic olefin may be mono-, di-, or tri-cyclic. When the cyclic olefin comprises more than one ring, the rings may or may not be fused. Preferred examples of cyclic olefins that comprise multiple rings include norbornene, dicyclopentadiene, tricyclopentadiene, and 5-ethylidene-2-norbornene.

The cyclic olefin may also be substituted, for example, a C₅ to C₂₄ cyclic hydrocarbon wherein one or more (typically 2, 3, 4, or 5) of the hydrogens are replaced with non-hydrogen substituents. Suitable non-hydrogen substituents may be chosen from the substituents described hereinabove. For example, functionalized cyclic olefins, i.e., C₅ to C₂₄ cyclic hydrocarbons wherein one or more (typically 2, 3, 4, or 5) of the hydrogens are replaced with functional groups, are within the scope of the disclosure. Suitable functional groups may be chosen from the functional groups described hereinabove. For example, a cyclic olefin functionalized with an alcohol group may be used to prepare a telechelic polymer comprising pendent alcohol groups. Functional groups on the cyclic olefin may be protected in cases where the functional group interferes with the metathesis catalyst, and any of the protecting groups commonly used in the art may be employed. Acceptable protecting groups may be found, for example, in Greene et al., Protective Groups in Organic Synthesis, 3rd Ed. (New York: Wiley, 1999). A non-limiting list of protecting groups includes: (for alcohols) acetyl, benzoyl, benzyl, β-Methoxyethoxymethyl ether (MEM), Dimethoxytrityl, [bis-(4-methoxyphenyl)phenylmethyl] (DMT), methoxymethyl ether (MOM), methoxytrityl [(4-methoxyphenyl)diphenylmethyl, MMT), p-methoxybenzyl ether (PMB), methylthiomethyl ether, pivaloyl (Piv), tetrahydropyranyl (THP), tetrahydrofuran (THF), trityl (triphenylmethyl, Tr), silyl ethers (most popular ones include trimethylsilyl (TMS), tert-butyldimethylsilyl (TBDMS), tri-iso-propylsilyloxymethyl (TOM), and triisopropylsilyl (TIPS) ethers, (for amines) tert-butyloxycarbonyl glycine, carbobenzyloxy (Cbz) group, p-methoxybenzyl carbonyl (Moz or MeOZ) group, tert-butyloxycarbonyl (BOC) group, 9-fluorenylmethyloxycarbonyl (FMOC) group, acetyl (Ac) group, benzoyl (Bz) group, benzyl (Bn), carbamate group, p-methoxybenzyl (PMB), 3,4-dimethoxybenzyl (DMPM), p-methoxyphenyl (PMP) group, tosyl (Ts) group, (for carbonyls) acetals and ketals, acylals, dithianes, (for carboxylic acids) methyl esters, benzyl esters, tert-butyl esters, esters of 2,6-disubstituted phenols (e.g. 2,6-dimethylphenol, 2,6-diisopropylphenol, 2,6-di-tert-butylphenol), silyl esters, orthoesters, oxazoline, (for phosphate) 2-cyanoethyl, and methyl. In the specific case of arginine (Arg) side chains, protection is important because of the propensity of the basic quanidinium group to produce side reactions. In cases described herein, effective protective groups include 2,2,5,7,8-pentamethylchroman (Pmc), 2,2,4,6,7-pentamethyldihydrobenzofurane (Pbf) and 1,2-dimethylindole-3-sulfonyl (MIS) groups.

Examples of functionalized cyclic olefins include without limitation 2-hydroxymethyl-5-norbornene, 2-[(2-hydroxyethyl)carboxylate]-5-norbornene, cydecanol, 5-n-hexyl-2-norbornene, 5-n-butyl-2-norbornene.

Cyclic olefins incorporating any combination of the abovementioned features (i.e., heteroatoms, substituents, multiple olefins, multiple rings) are suitable for the methods disclosed herein. Additionally, cyclic olefins incorporating any combination of the abovementioned features (i.e., heteroatoms, substituents, multiple olefins, multiple rings) are suitable for the invention(s) disclosed herein.

The cyclic olefins useful in the methods disclosed herein may be strained or unstrained. It will be appreciated that the amount of ring strain varies for each cyclic olefin compound, and depends upon a number of factors including the size of the ring, the presence and identity of substituents, and the presence of multiple rings. Ring strain is one factor in determining the reactivity of a molecule towards ring-opening olefin metathesis reactions. Highly strained cyclic olefins, such as certain bicyclic compounds, readily undergo ring opening reactions with olefin metathesis catalysts. Less strained cyclic olefins, such as certain unsubstituted hydrocarbon monocyclic olefins, are generally less reactive. In some cases, ring opening reactions of relatively unstrained (and therefore relatively unreactive) cyclic olefins may become possible when performed in the presence of the olefinic compounds disclosed herein.

A plurality of cyclic olefins may be used with the present disclosure to prepare metathesis polymers. For example, two cyclic olefins selected from the cyclic olefins described hereinabove may be employed in order to form metathesis products that incorporate both cyclic olefins. Where two or more cyclic olefins are used, one example of a second cyclic olefin is a cyclic alkenol, i.e., a C₅-C₂₄ cyclic hydrocarbon wherein at least one of the hydrogen substituents is replaced with an alcohol or protected alcohol moiety to yield a functionalized cyclic olefin.

The use of a plurality of cyclic olefins, and in particular when at least one of the cyclic olefins is functionalized, allows for further control over the positioning of functional groups within the products. For example, the density of cross-linking points can be controlled in polymers and macromonomers prepared using the methods disclosed herein. Control over the quantity and density of substituents and functional groups also allows for control over the physical properties (e.g., melting point, tensile strength, glass transition temperature, etc.) of the products. Control over these and other properties is possible for reactions using only a single cyclic olefin, but it will be appreciated that the use of a plurality of cyclic olefins further enhances the range of possible metathesis products and polymers formed.

More preferred cyclic olefins include dicyclopentadiene; tricyclopentadiene; dicyclohexadiene; norbornene; 5-methyl-2-norbornene; 5-ethyl-2-norbornene; 5-isobutyl-2-norbornene; 5,6-dimethyl-2-norbornene; 5-phenylnorbornene; 5-benzylnorbornene; 5-acetylnorbornene; 5-methoxycarbonylnorbornene; 5-ethoxycarbonyl-1-norbornene; 5-methyl-5-methoxy-carbonylnorbornene; 5-cyanonorbornene; 5,5,6-trimethyl-2-norbornene; cyclo-hexenylnorbornene; endo, exo-5,6-dimethoxynorbornene; endo, endo-5,6-dimethoxynorbornene; endo, exo-5-6-dimethoxycarbonylnorbornene; endo, endo-5,6-dimethoxycarbonylnorbornene; 2,3-dimethoxynorbornene; norbomadiene; tricycloundecene; tetracyclododecene; 8-methyltetracyclododecene; 8-ethyl-tetracyclododecene; 8-methoxycarbonyltetracyclododecene; 8-methyl-8-tetracyclo-dodecene; 8-cyanotetracyclododecene; pentacyclopentadecene; pentacyclohexadecene; higher order oligomers of cyclopentadiene such as cyclopentadiene tetramer, cyclopentadiene pentamer, and the like; and C₂-C₁₂ hydrocarbyl substituted norbornenes such as 5-butyl-2-norbornene; 5-hexyl-2-norbornene; 5-octyl-2-norbornene; 5-decyl-2-norbornene; 5-dodecyl-2-norbornene; 5-vinyl-2-norbornene; 5-ethylidene-2-norbornene; 5-isopropenyl-2-norbornene; 5-propenyl-2-norbornene; and 5-butenyl-2-norbornene, and the like. Even more preferred cyclic olefins include dicyclopentadiene, tricyclopentadiene, and higher order oligomers of cyclopentadiene, such as cyclopentadiene tetramer, cyclopentadiene pentamer, and the like, tetracyclododecene, norbornene, and C₂-C₁₂ hydrocarbyl substituted norbornenes, such as 5-butyl-2-norbornene, 5-hexyl-2-norbornene, 5-octyl-2-norbornene, 5-decyl-2-norbornene, 5-dodecyl-2-norbornene, 5-vinyl-2-norbornene, 5-ethylidene-2-norbornene, 5-isopropenyl-2-norbornene, 5-propenyl-2-norbornene, 5-butenyl-2-norbornene, and the like.

In certain embodiments, each of these Structures A-F may further comprise pendant substituents that are capable of crosslinking with one another or added crosslinking agents. For example, R^{A1}, R^{A2}, R^{B1}, R^{B2}, R^{B3}, R^{B4}, R^{B5}, R^{B6}, R^{C1}, R^{C2}, R^{C3}, R^{C4}, R^{C5}, R^{C6}, R^{D1}, R^{D2}, R^{D3}, R^{D4}, R^{E1}, R^{E2}, R^{E3}, R^{E4}, R^{E5}, R^{E6}, R^{E7}, R^{E8}, R^{F1}, R^{F2}, R^{F3}, and R^{F4} may independently represent pendant hydrocarbyl chains containing olefinic or acetylenic bonds capable of crosslinking with themselves or other unsaturated moieties under metathesis conditions. Additionally, within Structures A-F, at least one pair of substituents, R^{B1} and R^{B2}, R^{B3} and R^{B4}, and R^{B5} and R^{B6}, R^{C1} and R^{C2}, R^{C5} and R^{C6}, R^{D2} and R^{D3}, R^{E5} and R^{E6}, R^{E7} and R^{E8}, R^{F1} and R^{F2}, and R^{F3} and R^{F4}, can together form an optionally substituted exocyclic double bond, for example /═CH(C₁₋₆-Fn). This concept is specifically exemplified in the Examples, where a compound of Structure (F), where a is a single bond, g is 0, R^{F1}═R^{F2}═H, and R^{F3} and R^{F4} together form /═CH(ethyl) is reacted with oligomers of cyclooctadiene.

When considering alternative olefinic precursors in the present methods, more preferred precursors may be those which, which when incorporated into polyacetylene polymers or copolymers, modify the electrical or physical character of the resulting polymer. One general class of such precursors are substituted annulenes and annulynes, for example [18]annulene-1,4;7,10; 13,16-trisulfide. When co-polymerized with acetylene, this precursor can form a block co-polymer as shown here:

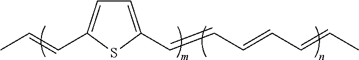

Substituted analogs of these trisulfides, as described below can also be used to provide corresponding substituted poly(thienylvinylene)-containing polymers or copolymers. For example, the 2,3,8,9,14,15-hexaoctyl derivative of [18]annulene-1,4;7,10; 13,16-trisulfide is described in Horie, et al., “Poly(thienylvinylene) prepared by ring-opening metathesis polymerization: Performance as a donor in bulk heterojunction organic photovoltaic devices,” Polymer 51 (2010) 1541-1547, which is incorporated by reference herein for all purposes

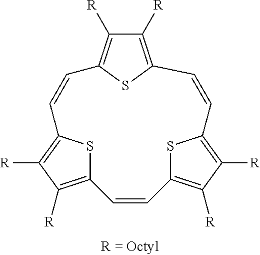

In certain embodiments, the unsaturated organic precursor comprises a purely hydrocarbon compound having a structure:

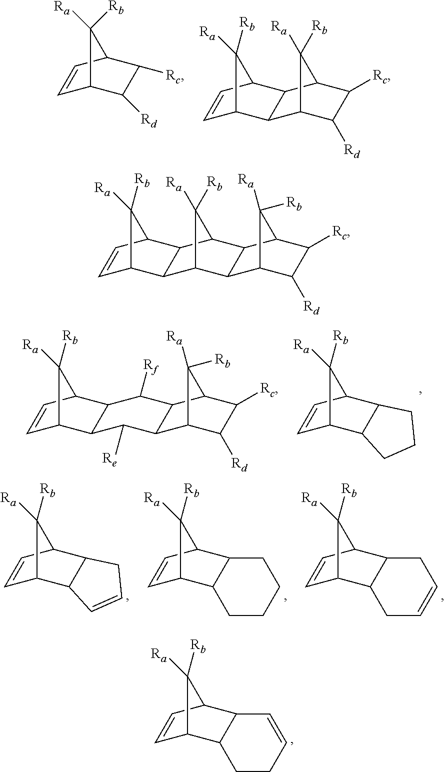

or a mixture thereof, wherein Rₐ, R_{b}, R_{c}, R_{d}, Rₑ, and R_{f} are independently H or alkyl (preferably C₁₋₂₀ alkyl, more preferably C₁₋₁₀ alkyl).

The unsaturated organic precursor may also comprise a hydrocarbon compound having a dicyclopentadiene structure, for example:

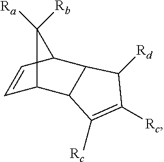

wherein Rₐ, R_{b}, R_{c}, R_{d}, Rₑ, and R_{f} are independently H or alkyl (preferably C₁₋₂₀ alkyl, more preferably C₁₋₁₀ alkyl). One such polymer resulting from such precursors comprises units having a structure:

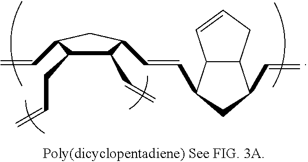

These hydrocarbon precursors are particularly attractive, for example, when the final polymerized product or article derived therefrom is to be subject to aggressive chemical conditions. For example, patterned products or article derived therefrom prepared from dicyclopentadiene structures are particularly effective in resisting aqueous HF, making them particularly attractive for use as etching masks in semi-conductor or other electronic processing. It is believe that the term “resistant to aqueous HF” carries a practical connotation understood by those skilled in the art; i.e., the patterned polymer layer is sufficiently robust as to withstand HF (or to slow the diffusion of fluoride ions from the protected surface) for a time sufficient to be practically useful in etch-processing or the polymer layer is not dissolved to a meaningful extent or the crosslinked polymer matrix is able to slow the diffusion of the HF (and fluoride ions) to protect the surface from these reactive species. Aqueous HF itself may be also characterized by its concentration, and in various embodiments, the concentration may be 5, 10, 15, 20, 25, 30, 35, 40, 45, or 48 wt %. For examples, in experiments using such compositions of the present disclosure, it was possible to selectively etch 30 micron posts in silicon dioxide (glass) in less than minute. Unless otherwise stated, the term “resistant to aqueous HF” is defined as being able to withstand exposure to aqueous HF at room temperatures (i.e., ca. 20-25° C.) for a period of 1 hour without measurable peeling from the substrate. Where specified, the term may also be defined in this way in terms of longer (e.g., 2, 3, 4, 5, 6, 12, 24, 48, or 96 hours) or shorter (e.g., 1, 5, 10, 20, 30, 40, or 50 minutes) exposure times. Such materials are also extremely tough and durable, and may be used in applications in bullet-proof vests and carbon fiber composites (e.g., as used in wind turbine blades)

In other embodiments, the unsaturated polymerizable material matrix may include mono-, di-, or polyfunctionalized cyclic or alicyclic alkenes or alkynes; i.e., which include functional groups, including for example, alcohols, amines, amides, carboxylic acids and esters, phosphines, phosphonates, sulfonates or the like. Optionally substituted bicyclo [2.2.1]hept-5-ene-2,3,dicarboxylic acid diesters, 7-oxa-bicyclo [2.2.1]hept-5-ene-2,3,dicarboxylic acid diesters, 4-oxa-tricyclo[5.2.1.0^{2,6}] dec-8-ene-3,5-diones, 4,10-dioxa-tricyclo[5.2.1.0^{2,6}] dec-8-ene-3,5-diones, 4-aza-tricyclo[5.2.1.0^{2,6}] dec-8-ene-3,5-diones, 10-oxa-4-aza-tricyclo[5.2.1.0^{2,6}] dec-8-ene-3,5-diones, or simple di-substituted alkenes, including bisphosphines may provide good results. In certain embodiments, these functionalized alkenes include those having structures such as:

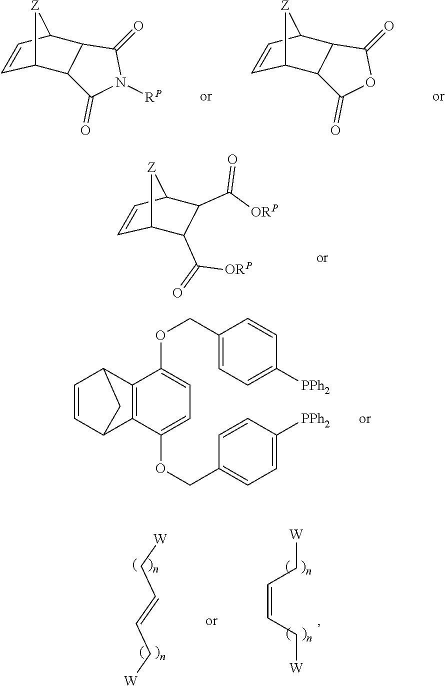

wherein

wherein

Z is —O— or C(Rₐ)(R_{b});

R^{P} is independently H; or C₁₋₆ alkyl optionally substituted at the terminus with —N(Rₐ)(R_{b}), —O—Rₐ, —C(O)O—Rₐ, —OC(O)—(C₁₋₆ alkyl), or —OC(O)—(C₆₋₁₀ aryl); or an optionally protected sequence of 3 to 10 amino acids (preferably including R-G-D or arginine-glycine-aspartic acid);

W is independently —N(Rₐ)(R_{b}), —O—Rₐ, or —C(O)O—Rₐ, —P(O)(ORₐ)₂, —SO₂(ORₐ), or SO₃—;

Rₐ and R_{b} are independently H or C₁₋₆ alkyl;

the C₆₋₁₀ aryl is optionally substituted with 1, 2, 3, 4, or 5 optionally protected hydroxyl groups (the protected hydroxyl groups preferably being benzyl); and

n is independently 1, 2, 3, 4, 5, or 6.

Non-limiting examples of such functionalized materials include:

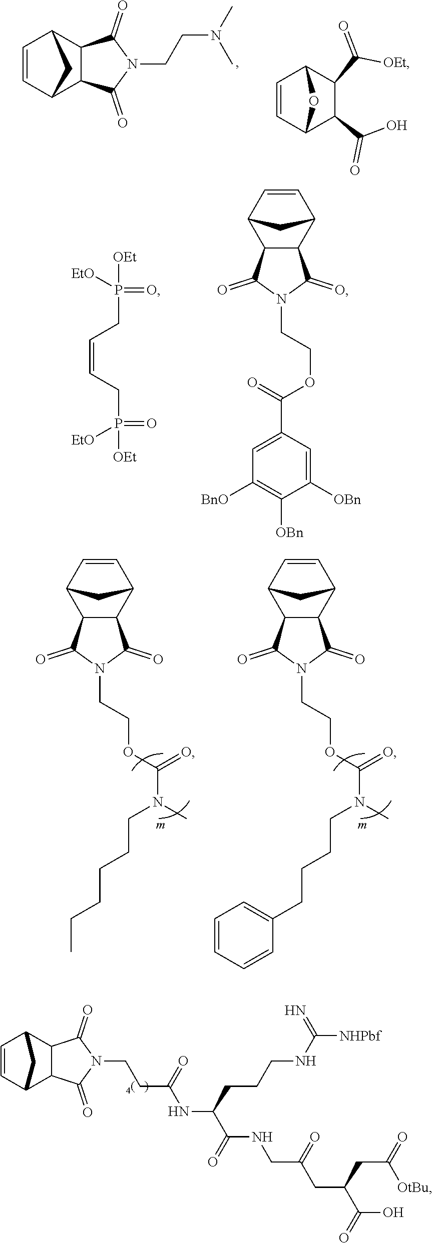

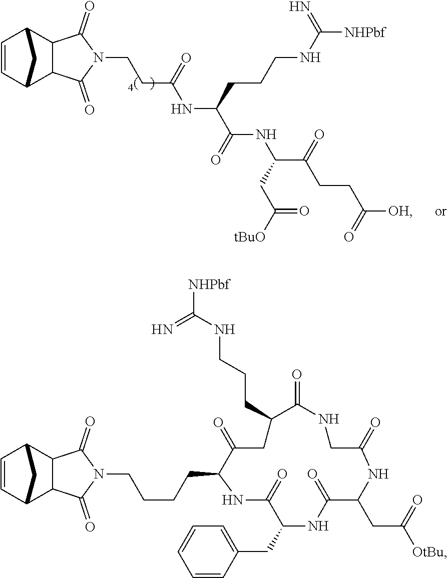

where Bn is benzyl, tBu is tert-butyl, and Pbf is 2,2,4,6,7-pentamethyldihydrobenzofuran. Other protecting groups may also be employed.

Incorporation of such functional groups provides for further functionalization of the pre-polymerized or polymerized compositions, thereby greatly expanding the utility options available for such compositions. Such functional groups, then, can be used as linking points for the additional of other materials, including, for example, natural or synthetic amino acid sequences. In certain embodiments, R^{P} can be further functionalized to include:

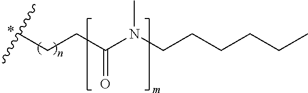

Polymerized products (either 2-dimensional optionally patterned coatings or optionally patterned 3-dimensional structures) prepared from the pre-polymerized compositions may be useful as scaffolds for drug delivery or tissue regeneration. Films or articles comprising pendant optionally protected sequence of 3 to 10 amino acids (preferably including R-G-D or arginine-glycine-aspartic acid) are known to be useful in tissue regeneration applications and the present inventive compositions and methods provide convenient routes to these materials

Building upon this concept of incorporating functionalized materials into or pendant to polymer matrices (either films or 3-dimensional articles) derived from photosensitive polymerizable matrices, the present inventors have also discovered that it is possible to incorporate catalytic organometallic materials into such matrices. In particular, the present invention(s) contemplates photosensitive compositions comprising a Fischer-type carbene ruthenium metathesis catalyst admixed or dissolved within a polymerizable material matrix comprising at least one unsaturated organic precursor and at least one unsaturated tethered organometallic precursor, or ligand capable of coordinating to form an organometallic precursor (e.g., vinyl bipyridine, bisphosphines, and carbene precursors) each organic and organometallic precursor having at least one alkene or one alkyne bond.

As used herein, the term “unsaturated tethered organometallic precursor” is defined as referring to organometallic complex having a pendant alkene or alkyne group capable of being incorporated into the polymerized matrix. This concept of tethering organometallic materials, including catalytic materials is well understood in chemistry, as such tethering methods are frequently used to immobilize homogenous catalysts onto stationary matrices (e.g., silica or alumina). By “tethered” or “tethering group,” it is appreciated by the person of skill in the art that this refers to linking groups, for example hydrocarbylene linking group such as an alkylene, substituted alkylene, heteroalkylene, substituted heteroalkene, arylene, substituted arylene, heteroarylene, or substituted heteroarylene linkage, including alkylene, arylene, amido, amino, or carboxylato. The specific nature of the linking group is not believed to be necessarily limiting, provided the group contains a reactive alkene or alkyne group capable of being incorporated into the polymerized matrix.

In some embodiments, the organometallic moiety comprises a Group 3 to Group 12 transition metal, preferably Fe, Co, Ni, Ti, Al, Cu, Zn, Ru, Rh, Ag, Ir, Pt, Au, or Hg. In preferred embodiments, the organometallic moiety comprises Fe, Co, Ni, Ru, Rh, Ag, Ir, Pt, or Au. The organometallic moieties may be attached by or contain monodentate, bidentate, or polydentate ligands, for example cyclopentadienyls, imidazoline (or their carbene precursors), phosphines, polyamines, polycarboxylates, nitrogen macrocycles (e.g., porphyrins or corroles), provided these ligands contain the pendant alkene or alkyne group capable of being incorporated into the polymerized matrix. Non-limiting examples of this concept include:

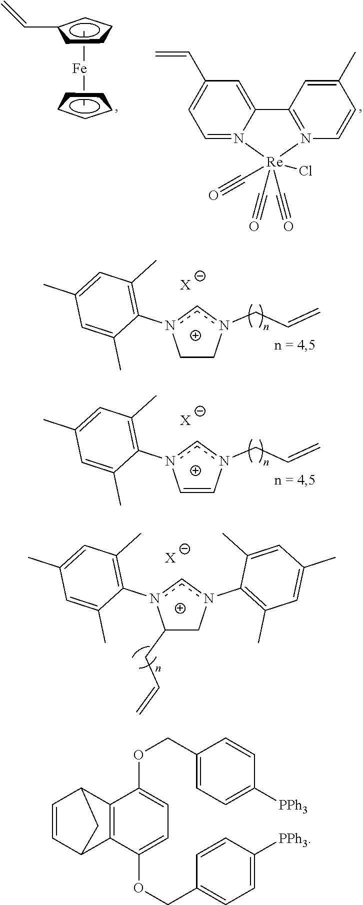

Representative chemistry of the polymerized product into which such an organometallic was incorporated is illustrated in U.S. patent application Ser. No. 14/505,824.

In certain embodiments, the organometallic moiety is chosen to be capable of catalyzing the oxidation or reduction of an organic substrate under oxidizing or reducing conditions. The terms “oxidizing or reducing conditions” are likewise generally understood by chemists skilled in the art, and include those conditions comprising the presence of oxidizing (oxygen, peroxides, etc.) or reducing (hydrogen, hydrides, etc.) agents. Such oxidation reactions include, but are not limited to, oxidations of alkenes or alkynes to form alcohols, aldehydes, carboxylic acids or esters, ethers, or ketones, or the addition of hydrogen-halides or silanes across unsaturates. Such oxidation reactions include, but are not limited to, reduction of alkenes to alkanes and reduction of alkynes to alkenes or alkanes. Certain of these organometallic moieties may be used as pendant metathesis or cross-coupling catalysts or for splitting water.

Metatheses Reactions

The metathesis reactions contemplated by the present disclosure include Ring-Opening Metathesis Polymerization (ROMP), Ring-Closing Metathesis (RCM), and Cross Metathesis (CM). While often described in terms of“olefin metathesis,” it should also be understood that both olefinic and acetylenic bonds can participate in such reactions, and so as used herein, the term “olefin metathesis” is to be interpreted as involving the redistribution of olefinic or acetylenic bonds. Each of these types of reactions is well known to those skilled in the relevant art in this capacity.

In those contemplated embodiment related to photoresists (to be described further infra), the descriptions are generally provided in terms of selective polymerizations, for example by ROMP or cross-metathesis, so as to provide spatially specific regions of cross-linked polymers. But it should also be appreciated that this spatial and temporal selectivity available by the photoactivated catalysts may also be applied to change the solubility properties of the irradiated region without crosslinking—for example by only partial reaction of the precursors, cross metathesis of an olefinic precursor with a polymer, or through depolymerization.

Photosensitive Compositions, Including Photoresists

As should be appreciated by the descriptions herein, one of the several features of the present disclosure is the ability to spatially and temporally control the catalytic activities of the systems with remarkable precision, owing to the high contrast in activity between the irradiated and unirradiated catalysts. The high activities of the irradiated catalysts allows for good activity, even at low embedded catalyst concentrations. In some embodiments, the Fischer-type carbene ruthenium metathesis catalyst is present at a concentration in a range of from about 0.001% to about 5% by weight, relative to the weight of the entire composition. This concentration range depends on the reactivities of the catalyst and the polymerizable material precursors, the desired handling conditions, and the desired rates of polymerization. In certain other embodiments, ruthenium carbene metathesis catalyst is present at a concentration in a range of from about 0.001% to about 0.01%, from about 0.01% to about 0.1%, from about 0.1% to about 1%, from about 1% to about 2%, from about 2% to about 3%, from about 3% to about 4%, from about 4% to about 5%, or a combination thereof, all by weight, relative to the weight of the entire composition. The systems also allow for higher concentrations, for example up to about 10 or 15% by weight, relative to the weight of the entire composition, but here cost begins to become dissuasive for most practical applications.

As described above, the methods of the present disclosure also consider that the Fischer-type carbene ruthenium metathesis catalyst, as described herein, may be dissolved in a solvent in the presence of at least one unsaturated organic precursor or are admixed or dissolved in at least one unsaturated organic precursor. In the circumstances where the user contemplates the use of these compositions as photoresists, the Fischer-type catalyst may be added to the organic precursor directly or generated in situ as described elsewhere herein. This in situ generation of the catalyst may involve providing a catalyst containing a Schrock-type carbene, which is subsequently quenched to form the Fischer-type carbene catalyst. If so, the generation of the catalyst may be accompanied by partial polymerization or cross-linking of the originally added organic precursor, and the intermediate viscosity of this partial polymerized or cross-linked composition may be controlled by the time before quenching. Raising the viscosity of the photosensitive compositions provides several advantages, including improving the oxidative stability of the otherwise potentially air-sensitive catalysts. The raised viscosity also controls the diffusion length of the active catalyst species through the composition, which in turn can improve the resolution of the lithographically defined structures.

In some embodiments, it is convenient to use a non-reactive solvent (low boiling solvents may be preferred, such as methylene chloride, tetrahydrofuran, diethyl ether, toluene, etc.) to provide and maintain lower initial viscosities, so as to allow for more efficient intimate mixing of the catalyst within the total composition. In the case of the phenanthroline-ligated catalysts derivatives described herein, use of more reactive solvents, including water, acetonitrile, and chloroform, may be tolerable. Once the catalyst is intimately distributed within the composition, the non-reactive solvent may be conveniently removed, for example under vacuum or with heat. In some cases, once the Fischer-type catalyst is added or prepared, additional or different organic precursor may be added to dilute the catalyst further. The viscosity of the final, unexposed product may be adjusted by the type and amount of the constituents. For example, in some embodiments, the viscosity is such that the composition is suitable for spin-coating, dip coating, or spraying. In other embodiments, the photosensitive composition can have the form of a gelled, solid, or semi-solid film. In various independent embodiments, the viscosity of the composition, at the contemplated temperature of application (preferably ambient room temperature) is in a range of from about 1 cSt to about 10 cSt, from about 10 cSt to about 50 cSt, from about 50 cSt to about 100 cSt, from about 100 cSt to about 250 cSt, from about 250 cSt to about 500 cSt, from about 500 cSt to about 1000 cSt, from about 1000 cSt to about 2000 cSt, from about 2000 cSt to about 5000 cSt, or higher. Higher viscosities appear provide increased oxidative stability of the ruthenium carbene catalysts.

Part of the challenge in developing an olefin metathesis-based photoresist is achieving a stark contrast between the reactivity of the catalyst in the light and the dark. Additionally, the requirements of ambient stability and processability present barriers to the industrial implementation of transition metal based photocatalysts. In the present disclosure, certain embodiments provide that a standard quenching procedure for ROMP or cross-metathesis reactions generates a latent photoactive catalyst. This serendipitous discovery allows for the facile synthesis of a new family of photocurable materials. The addition of substituted vinyl ethers is a widely employed method of quenching ROMP or cross-metathesis reactions. The regioselective formation of vinyl ether complexes, for example, is extremely rapid and irreversible under certain conditions, leading to the use of vinyl ether “trapping” as a tool for determining catalyst initiation rates. The resultant ruthenium Fischer-type carbenes are generally considered to be unreactive. While not intending to be bound by the correctness or incorrectness of any particular theory, it appears that quenching a living ROMP reaction yields a methylene-terminated polymer chain and a presumably 14-electron ruthenium vinyl ether. While the phosphine or pyridine ligands typically found on ruthenium ROMP catalysts could in principle re-coordinate to the quenched complex, the statistical likelihood of this is extremely low considering the concentration and stoichiometry of typical ROMP reactions. In addition, the air-sensitivity of the ruthenium vinyl ether complexes aids in the quenching process, through almost immediate decomposition of the alkylidene species. A typical quenching procedure utilizes excess vinyl ether and immediate precipitation of the polymer to remove the catalyst. Interestingly, the addition of bipyridine ligands, appears to reduce the nascent reactivity of these catalysts even further, while allowing highly efficient photoactivation, such that the metathesis reactivity is only unleashed by irradiation with light. This enables moderate heating to be applied as part of the patterning process, enabling pre- or post-exposure baking steps to be implemented.

The photosensitive compositions, including photoresists, may additionally comprise other materials, so long as their presence does not interfere with the ability of the photoactivated catalysts to effect the metathesis reactions under irradiation conditions. For example, these compositions, including photoresists, may contain colorants, surfactants, and stabilizers, as well as functional particles including, for example, nanostructures (including carbon and inorganic nanotubes), magnetic materials (e.g., ferrites), and quantum dots.

Methods of Patterning a Polymer on a Substrate

Embodiments of the present disclosure also provide methods of providing patterned polymer layers using the Fischer-type carbene photocatalysts, which may be described as PhotoLithographic Olefin Metathesis Polymerization (PLOMP). In this procedure, a latent metathesis catalyst is activated by light to react with the olefins in the surrounding environment, providing for the development of a negative tone resist by using the photocatalyst to polymerize, crosslink, or both polymerize and crosslink a difunctional ROMP monomer or other unsaturated precursor within a polymerizable material matrix of linear polymer or polymer precursor. In principle, a positive tone resist can also be developed, by using light-triggered secondary metathesis events to increase the solubility of the irradiated regions. This can be considered a “chemically amplified” resist, in that the photoactive species is a catalyst for the crosslinking of the polymer matrix. The versatility of these ruthenium-mediated olefin metathesis reactions can now be utilized to photopattern a variety of functional materials via PLOMP, advancing the field of photoinitiated olefin metathesis from a curiosity to materials science applicable to mass microfabrication.

Some embodiments provide methods of patterning a polymeric image on a substrate, each method comprising;

(a) depositing a layer of photosensitive composition of any one of the compositions described herein on the substrate;

(b) irradiating a portion of the layer of photosensitive composition with a light having appropriate wavelength(s), as described elsewhere herein, thereby providing a patterned layer of polymerized and unpolymerized regions. Certain other embodiments further comprise removing the unpolymerized region of the pattern.

In principle, the substrates can comprise any metallic or non-metallic; organic or inorganic; conductive, semi-conductive, or non-conductive material, or any combination thereof. Even so, it is contemplated that these patterned polymer layers will find utility in electronic applications including those where semiconductor wafers comprising silicon, GaAs, and InP. One of the many advantages of these inventive systems, certainly over many commercial resists, is the ability to maintain surface adhesion to the native oxide surfaces of silicon wafers, for example, without any etching or surface derivatization. By contrast, many commercial photoresists require HF etching of the oxide and/or surface derivatization with reactive molecules such as hexamethyldisilazane. In this respect, the presently described photosensitive systems offer a safer and more versatile alternative, as the polymer composition can be easily tuned to modulate adhesion. For examples, in the examples described herein, the poly(COD) resist batches showed excellent adhesion to silicon coupons, which were first cleaned with piranha. Additionally, the PLOMP resists do not require post-exposure baking to develop. Currently, ruthenium-mediated ROMP is employed in a number of industrial scale applications, including high-modulus resins and extremely chemically resistant materials. PLOMP can provide UV-curable and patternable coatings with these desired materials properties. Finally, the ability to generate many batches of resist in a single workday enables rapid prototyping for future development.

In some embodiments, the patterned polymers may be processed to form single layer or multilayer polymer structures. In multilayer structures, each layer may be the same or different than any other of the deposited layer, and may be individually patterned as described herein. Similarly, each layer may be interleaved with intermediately deposited metal, metal oxide, or other material layer. These interlayers may be deposited for example by sputtering, or other chemical or vapor deposition technique, provided the processing of these interlayers does not adversely affect the quality of the patterned layers of deposited polymers.

The photosensitive compositions may be deposited by spin coating, dip coating, or spray coating, or alternatively, depending on the physical form of the photosensitive composition, may be deposited by laminating a gelled or solid film on the substrate.

The photosensitive compositions may be irradiated by any variety of methods known in the art. In certain embodiments, patterning may be achieved by photolithography, using a positive or negative image photomask. In other embodiments, patterning may be achieved by interference lithography (i.e., using a diffraction grating). In other embodiments, patterning may be achieved by proximity field nanopatterning. In still other embodiments, patterning may be achieved by diffraction gradient lithography. In still other embodiments, patterning may be used by a direct laser writing application of light, such as by multi-photon lithography. Additional embodiments provide that the patterning may be accomplished by nanoimprint lithography. Further, the patterning may be accomplished by inkjet 3D printing, stereolithography and the digital micromirror array variation of stereolithography (commonly referred to as digital light projection (DLP). These inventive compositions are especially amenable to preparing structures using stereolithographic methods, for example including digital light projection (DLP) (see Examples). In some embodiments, the photosensitive compositions may be processed as bulk structures, for example using vat polymerization, wherein the photopolymer is cured directly onto a translated or rotated substrate, and the irradiation is patterned via stereolithography, holography, or digital light projection (DLP). “Stereolithography” is a method and apparatus for making solid objects by successively “printing” thin layers of a curable material, e.g., a UV curable material, one on top of the other. A programmed movable spot beam of UV light shining on a surface or layer of UV curable liquid is used to form a solid cross-section of the object at the surface of the liquid. The object is then moved, in a programmed manner, away from the liquid surface by the thickness of one layer, and the next cross-section is then formed and adhered to the immediately preceding layer defining the object. This process is continued until the entire object is formed. Such methods are summarized and described in U.S. Pat. No. 5,571,471, which is incorporated by reference herein in its entirety for its teaching of such methods.

The Fischer-type carbene ruthenium metathesis catalysts can be activated using light having at least one wavelength in a range of from about 300 to about 500 nm. Additional embodiments provide that the light comprises at least one wavelength in a range of from about 300 to about 320 nm, from about 320 to about 340 nm, from about 340 to about 360 nm, from about 360 to about 380 nm, from about 380 to about 400 nm, from about 400 to about 420 nm, from about 420 to about 440 nm, from about 440 to about 460 nm, from about 460 to about 480 nm, from about 480 to about 5000 nm, or a combination thereof. In other preferred embodiments, this wavelength is in a range of from about 380 to about 420 nm. As described above, the intensity of this at least wavelength is in a range of about 1 mW/cm² to 10 W/cm², preferably about 10 mW/cm² to 200 mW/cm². In specific embodiments, the intensity of the photoactivating source may be in a range of from about 1 mW/cm² to about 5 mW/cm², from about 5 mW/cm² to about 10 mW/cm², from about 10 mW/cm² to about 50 mW/cm², from about 50 mW/cm² to about 100 mW/cm², from about 100 mW/cm² to about 200 mW/cm², from about 200 mW/cm² to about 300 mW/cm², from about 300 mW/cm² to about 400 mW/cm², from about 400 mW/cm² to about 500 mW/cm², from about 500 mW/cm² to about 1 W/cm², from about 1 W/cm² to about 5 W/cm², from about 5 W/cm² to about 10 W/cm², or any combination of two or more of these ranges. In certain aspects, the catalysts can be activated using 2- or 3-photon energy sources at 700 to 800 nm, more specifically using a 790 nm laser. This two-photon energy is equivalent to 395 nm; the 3-photon energy is equivalent to about 263 nm).

The dimensions of the resulting features of the polymerized structures are, in part, dictated by the wavelength of the irradiating light, the method of irradiation, and the character of the photosensitive compositions. Higher viscosities and the optional presence of additional quenchants may usefully minimize diffusion of the catalyst in the composition, so as to provide for better resolution. In certain embodiments, the polymerized polymer exhibits features (e.g., channels, ridges, holes, or posts) having dimensions on the millimeter scale (e.g., from about 1 mm to about 10 mm, from about 10 mm to about 50 mm, from about 50 mm to about 100 mm, from about 100 mm to about 500 mm, from about 500 mm to about 1000 mm, or a combination thereof), the micron scale (e.g., from about 1 micron to about 10 microns, from about 10 microns to about 50 microns, from about 50 microns to about 100 microns, from about 100 microns to about 500 microns, from about 500 microns to about 1000 microns, or a combination thereof), or the nanometer scale (e.g., from about 1 nm to about 10 nm, from about 10 nm to about 50 nm, from about 50 nm to about 100 nm, from about 100 to about 200 nm, from about 200 to about 300 nm, from about 300 to about 400 nm, from about 400 to about 500 nm, from about 500 to about 600 nm, from about 600 to about 700 nm, from about 700 to about 800 nm, or a combination thereof. Interference or diffraction gradient lithography may provide for polymer layers having continuous or discontinuous thicknesses.

The methods and derived polymer products may generally serve as masks or templates for chemical etching processes. Polymers made by these processes are qualitatively stable to dichloromethane, isopropanol, acetone, 2.5 M hydrochloric acid, and concentrated sulfuric acid. after being submerged for approximately 24 hours.

Three-Dimensional Structures

The present disclosure(s) also provides compositions and methods suitable for making 3-dimensional structures comprising a plurality of polymer layers and 3-dimensional patterns. The ability to provide specifically dimensioned patterns makes these structures particularly useful, for example, in 3-dimensional photonic or chemochromic devices.

In certain embodiments, such structures are prepared by methods comprising:

(a) depositing at least two layers of a polymerizable material composition having at least one alkene or alkyne capable of undergoing a metathesis polymerization or crosslinking reaction and an appropriate photocatalyst, at least one of these layers containing the ruthenium bipyridine complexes described herein acting in this capacity, the deposition forming a stacked assembly;

(b) irradiating at least a portion of the stacked assembly with light, such that light penetrates and irradiates at least two layers of the stacked assembly, under conditions sufficient to polymerize or crosslink at least portions of adjacent layers of the stacked assembly In related embodiments, the portions of the assembly not reacted may be subsequently removed.

These layers of polymerizable materials generally, but not necessarily, comprise mainly polymers, with the additional presence of small amounts of polymerizable precursors or crosslinkers. That is, each layer may comprise at least 50%, 60%, 70%, 80%, 90%, 95%, or 98% by weight of preformed polymer, the weight percentage based on the total weight of the layers of a polymerizable material.

In some embodiments, one or more of the at least two layers of a polymerizable material may contain residual ruthenium metathesis catalyst that was used to prepare that particular layer. That is, that layer may have already been derived from a ROMP-type catalysis synthesis, and have residual catalyst contained therein. Alternatively, additional or new ruthenium metathesis catalyst may be admixed or dissolved within a pre-prepared layer of a polymerizable material by dissolving it in the presence of a solvent (as described herein) or incorporating the catalyst into a solvent swelled.

Such layer or layers may also contain residual polymer precursor from the original (incomplete) polymerization or contain residual less reactive polymer precursors. Alternatively, the layer may have had additional polymerizable or crosslinkable materials added to it, for example by dissolving or swelling the layer in the presence of the additional polymerizable or crosslinkable material. Such residual precursors are akin to those described herein. Other chemical cross-linkers are known in the art.

The stacked assembly may be formed to comprise adjacent layers having materials of similar composition. Alternatively, adjacent layers may be compositionally different. Or the stacked assembly may comprise a combination of adjacent layers being compositionally the same and different. In preferred embodiments, each layer of the stacked assembly comprises a pre-formed polymer having different chemistries from other pre-formed polymer(s) in the other layer(s). Individual layers within the stacked assembly may have thickness of any practical dimension, but particular embodiments include those where the thickness of each layer is independently on the millimeter scale (e.g., from about 1 mm to about 10 mm, from about 10 mm to about 50 mm, from about 50 mm to about 100 mm, from about 100 mm to about 500 mm, from about 500 mm to about 1000 mm, or a combination thereof), the micron scale (e.g., from about 1 micron to about 10 microns, from about 10 microns to about 50 microns, from about 50 microns to about 100 microns, from about 100 microns to about 500 microns, from about 500 microns to about 1000 microns, or a combination thereof), or the nanometer scale. In the latter case, the layers may be independently in a range of from about 50 to about 100 nm, from about 100 to about 200 nm, from about 200 to about 300 nm, from about 300 to about 400 nm, from about 400 to about 500 nm, from about 500 to about 600 nm, from about 600 to about 700 nm, from about 700 to about 800 nm, from about 800 to about 900 nm, from about 900 to about 1000 nm, or a combination thereof. By selecting the thickness and optical characteristics of adjacent layers, it is possible to tune the optics of the entire device.

In certain cases, the layers of the polymerizable material compositions may be deposited sequentially upon one another or may be allowed to self-assemble to the stacked assembly when different materials are mixed together in a liquid. Self-assembly would appear to be a more intimate and useful way of forming such stacked structures, particularly at the nano-scale dimensions useful for photonic or chemochromic devices, but the ability to self-assemble effectively depends on the nature of the various layers. For example, certain block copolymers are able to self-assemble providing lateral and vertical domains having dimensions in a range of from about 5 to about 1500 nanometer, preferably in a range of from about 75 to about 300 nm domains. As such, layers comprising block copolymers are useful materials to be incorporated in these methods. Brush (graft) block, wedge-type block, and hybrid wedge and polymer block copolymers. See FIG. 6. Such block copolymers are described in copending U.S. Patent Application Publication Nos. 2014/0011958, 2013/0296491, and 2013/0324666 and in Piunova, et al., J. Amer. Chem. Soc, 2013, 135 (41), pp 15609-15616, Miyake, G. M., et al., Angewandte Chemie International Edition 2012, 51, 11246-11248, Sveinbjörnsson, B. R., et al., PNAS 2012, 109, 14332-14336, and Miyake, G. M., et al., J. Am. Chem. Soc. 2012, 134, 14249-14254, each of which is incorporated by reference for their description of the polymers and copolymers. These compositions are considered especially attractive materials to be used in these methods, though the methods are not limited to these choices of materials.

Once the stacked assembly is formed, at least a portion of it is subject to irradiation with light, under conditions described herein, such that light penetrates and irradiates at least two layers of the stacked assembly, under conditions sufficient to polymerize or crosslink at least portions of adjacent layers of the stacked assembly. Whereas the adjacent layers could be delaminated prior to irradiation, the application of light activates the incorporated ruthenium metathesis catalyst to crosslink these adjacent layers to a coherent structure. In other embodiments, the light is directed to pass through and irradiate at least a portion of all of the layers of the stacked assembly. In other embodiments, the entire structure is irradiated with light under conditions to crosslink the entire assembly.

Whereas a stacked assembly can be irradiated in its entirety, another set of embodiments provide that the irradiating is done by patterned exposure of light to the stacked assembly, so as to provide a three-dimensional pattern of polymerized and unpolymerized regions through the stacked assembly. Much like the compositions provide that patterned irradiation of planar polymer layers can give rise to nano- and micro-dimensioned patterns, for example by using a direct writing application of light or by interference, nanoimprint, or diffraction gradient lithography, so too can this same patterning technology be used to form similarly dimensioned patterns in 3-dimensions. Once selectively polymerized or crosslinked, the unreactive portions of the structure may be removed.

As expected, embodiments of the present disclosure include those structures prepared using these methods, and articles incorporating these structures. Photonic devices, including chemochromic sensors, solar cells, dielectric mirrors, and reflective coatings are contemplated embodiments.

### Additional Embodiments

The following listing of embodiments in intended to complement, rather than displace or supersede, the previous descriptions.

### Embodiment 1

A photosensitive composition comprising a ruthenium carbene metathesis catalyst of Formula (I) or a geometric isomer thereof:

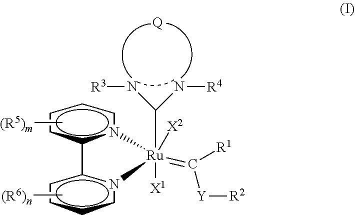

admixed within a polymerizable material matrix comprising at least one unsaturated organic precursor, including ROMP or cross-metathesis precursors;

wherein

X¹ and X² are independently anionic ligands;

Y is O, N—R¹, or S, preferably O; and

Q is a two-atom linkage having the structure —CR¹¹R¹²—CR¹³R¹⁴— or —CR¹¹═CR¹³—, preferably —CR¹¹R¹²—CR¹³R¹⁴—, wherein R¹¹, R¹², R¹³, and R¹⁴ are independently hydrogen an an optionally substituted hydrocarbyl;

R¹ and R² are independently hydrogen, optionally substituted hydrocarbyl, or may be linked together to form an optionally substituted cyclic aliphatic group;

R³ and R⁴ are independently optionally substituted hydrocarbyl; and

R⁵ and R⁶ are independently H, C₁₋₂₄alkyl, C₁₋₂₄alkoxy, C₁₋₂₄fluoroalkyl, C₁₋₂₄fluoroalkoxy, C₁₋₂₄alkylhydroxy, C₁₋₂₄alkoxyhydroxy, C₁₋₂₄fluoroalkylhydroxy(including perfluoroalkylhydroxy), C₁₋₂₄fluoroalkoxyhydroxy, halo, cyano, nitro, or hydroxy; and

m and n are independently 1, 2, 3, or 4.

The ruthenium carbene metathesis catalyst of Formula (I) may be added as described here or generated in situ as described herein. The independent X¹ and X² are anionic ligands are believed to be positioned cis with respect to one another, though the compounds may also be present as geometric isomers of the structure presented.

### Embodiment 2

The photosensitive composition of Embodiment 1, wherein the Ru═C(R¹)(Y—R²) moiety is a substituted vinyl ether carbene. In certain Aspects of this Embodiment, R² is C₁₋₆ alkyl, preferably ethyl, propyl, or butyl; that is, R¹ is H, R² is C₁₋₆ alkyl, and Y is O.

### Embodiment 3

The photosensitive composition of Embodiment 1 or 2, wherein Q is —CH₂—CH₂— and either R³ or R⁴, or both R³ and R⁴ are optionally substituted phenyl groups, optionally substituted at least in the 2, 6 positions with independent C₁₋₆ alkyl groups, preferably C₃₋₆ alkyl groups which may be branched or linear, e.g., including methyl, ethyl, n-propyl, iso-propyl, n-butyl, sec-butyl, tert-butyl. Additionally, the phenyl groups may be optionally substituted in the 4-positions with an electron-withdrawing or -donating group as described herein, for example, alkyl, alkoxy, nitro, or halo.

### Embodiment 4

The photosensitive composition of any one of Embodiments 1 to 3, wherein Q is —CH₂—CH₂— and R³ and R⁴ are independently mesityl or optionally substituted adamantyl.

### Embodiment 5

The photosensitive composition of any one of Embodiments 1 to 4, wherein R⁵ and R⁶ are independently H, methyl, ethyl, propyl, butyl, methoxy, trifluoromethyl, fluoro, chloro, bromo, cyano, or nitro.

### Embodiment 6

The photosensitive composition of any one of Embodiments 1 to 5, wherein the optionally substituted 2,2′-bipyridine is substituted with R⁵ and R⁶ in the 3,3′ or 4,4′ or 5,5′ or 6,6′ positions

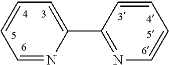 [SMILES: c1ccc(-c2ccccn2)nc1]

In other Aspects of this Embodiment, one or more of R⁵ may be present in any one or more of the 3, 4, 5, or 6 positions, and R⁶ may be independently present in any one or more of the 3′, 4′, 5′, or 6′ positions

### Embodiment 7

The photosensitive composition of any one of Embodiments 1 to 6, where the metathesis catalyst comprises a compound having a structure:

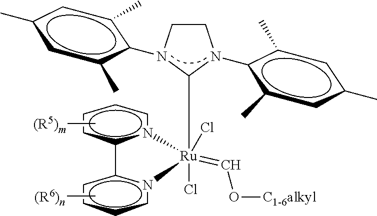

including a corresponding structure generated in situ.

### Embodiment 8

The photosensitive composition of any one of Embodiments 1 to 7, wherein the ruthenium metathesis catalyst is present at a concentration in a range of from about 0.001% to about 5% by weight, relative to the weight of the entire composition.

### Embodiment 9

The photosensitive composition of any one of Embodiments 1 to 8, wherein the ruthenium carbene catalyst, upon activation by irradiation of light of at at least one wavelength in a range of from about 250 nm to about 800 nm, preferably from about 350 nm to about 450 nm or in a range of from about 380 to about 420 nm, can crosslink or polymerize at least one of the unsaturated organic precursor. In other Aspects of this Embodiment, the light comprises at least one wavelength in a range of from about 250 to about 300 nm, from about 300 to about 320 nm, from about 320 to about 340 nm, from about 340 to about 360 nm, from about 360 to about 380 nm, from about 380 to about 400 nm, from about 400 to about 420 nm, from about 420 to about 440 nm, from about 440 to about 460 nm, from about 460 to about 480 nm, from about 480 to about 500 nm, from about 500 to about 600 nm, from about 600 to about 700 nm, from about 700 to about 800 nm, or a combination thereof.

### Embodiment 10

The photosensitive composition of any one of Embodiments 1 to 9, wherein the unsaturated organic precursor comprises one alkene, alkyne, or both alkene and alkyne moieties and is capable of polymerizing when metathesized. In some Aspects of this Embodiment, the unsaturated precursor comprises a mono-unsaturated cyclic olefin; a monocyclic diene; or a bicyclic or polycyclic olefin.

### Embodiment 11

The photosensitive composition of any one of Embodiments 1 to 10, wherein the unsaturated organic precursor is a ROMP precursor.

### Embodiment 12

The photosensitive composition of any one of Embodiments 1 to 11, wherein the unsaturated organic precursor comprises:

(a) a mono-unsaturated cyclic olefin represented by the structure (B)

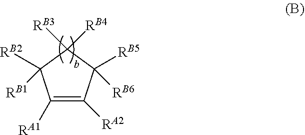

wherein b is an integer generally although not necessarily in the range of 1 to 10, typically 1 to 5,

R^{A1} and R^{A2} are independently hydrogen, hydrocarbyl (e.g., C₁-C₂₀ alkyl, C₅-C₂₀ aryl, C₅-C₃₀ aralkyl, or C₅-C₃₀ alkaryl), substituted hydrocarbyl (e.g., substituted C₁-C₂₀ alkyl, C₅-C₂₀ aryl, C₅-C₃₀ aralkyl, or C₅-C₃₀ alkaryl), heteroatom-containing hydrocarbyl (e.g., C₁-C₂₀ heteroalkyl, C₅-C₂₀ heteroaryl, heteroatom-containing C₅-C₃₀ aralkyl, or heteroatom-containing C₅-C₃₀ alkaryl), and substituted heteroatom-containing hydrocarbyl (e.g., substituted C₁-C₂₀ heteroalkyl, C₅-C₂₀ heteroaryl, heteroatom-containing C₅-C₃₀ aralkyl, or heteroatom-containing C₅-C₃₀ alkaryl) and, if substituted hydrocarbyl or substituted heteroatom-containing hydrocarbyl, wherein the substituents may be functional groups (“Fn”) such as alkene, alkyne, phosphonato, phosphoryl, phosphanyl, phosphino, sulfonato, C₁-C₂₀ alkylsulfanyl, C₅-C₂₀ arylsulfanyl, C₁-C₂₀ alkylsulfonyl, C₅-C₂₀ arylsulfonyl, C₁-C₂₀ alkylsulfinyl, C₅-C₂₀ arylsulfinyl, sulfonamido, amino, amido, imino, nitro, nitroso, hydroxyl, C₁-C₂₀ alkoxy, C₅-C₂₀ aryloxy, C₂-C₂₀ alkoxycarbonyl, C₅-C₂₀ aryloxycarbonyl, carboxyl, carboxylato, mercapto, formyl, C₁-C₂₀ thioester, cyano, cyanato, thiocyanato, isocyanate, thioisocyanate, carbamoyl, epoxy, styrenyl, silyl, silyloxy, silanyl, siloxazanyl, boronato, boryl, or halogen, or a metal-containing or metalloid-containing group (wherein the metal may be, for example, Sn or Ge); and

R^{B1}, R^{B2}, R^{B3}, R^{B4}, R^{B5}, and R^{B6} are independently selected from the group consisting of hydrogen, hydrocarbyl, substituted hydrocarbyl, heteroatom-containing hydrocarbyl, substituted heteroatom-containing hydrocarbyl and —(Z*)ₙ-Fn where Z* is a hydrocarbylene linking group such as an alkylene, substituted alkylene, heteroalkylene, substituted heteroalkene, arylene, substituted arylene, heteroarylene, or substituted heteroarylene linkage; and

wherein if any of the R^{B1} through R^{B6} moieties is substituted hydrocarbyl or substituted heteroatom-containing hydrocarbyl, the substituents may include one or more —(Z*)ₙ-Fn groups; or

(b) a monocyclic diene represented by the structure (C)

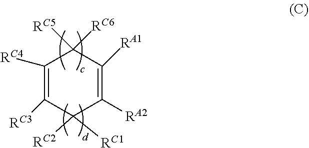

wherein c and d are independently integers in the range of 1 to about 8, typically 2 to 4, preferably 2 (such that the reactant is a cyclooctadiene);

R^{C1}, R^{C2}, R^{C3}, R^{C4}, R^{C5}, and R^{C6} are defined as corresponding to R^{B1} through R^{B6}; or

(c) a bicyclic or polycyclic olefin represented by the structure (D)

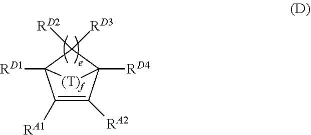

wherein

R^{D1}, R^{D2}, R^{D3}, and R^{D4} are as defined as corresponding to R^{B1} through R^{B6},

e is an integer in the range of 1 to 8 (typically 2 to 4)

f is generally 1 or 2;

T is lower alkylene or alkenylene (generally substituted or unsubstituted methyl or ethyl), CHR^{G1}, C(R^{G1})₂, O, S, N—R^{G1}, P—R^{G1}, O═P—R^{G1}, Si(R^{G1})₂, B—R^{G1}, or As—R^{G1} where R^{G1} is alkyl, alkenyl, cycloalkyl, cycloalkenyl, aryl, alkaryl, aralkyl, or alkoxy. Furthermore, any of the R^{D1}, R^{D2}, R^{D3}, and R^{D4} moieties can be linked to any of the other R^{D1}, R^{D2}, R^{D3}, and R^{D4} moieties to provide a substituted or unsubstituted alicyclic group containing 4 to 30 ring carbon atoms or a substituted or unsubstituted aryl group containing 6 to 18 ring carbon atoms or combinations thereof and the linkage may include heteroatoms or functional groups, e.g. the linkage may include without limitation an ether, ester, thioether, amino, alkylamino, imino, or anhydride moiety; or

(d) a norbornenes represented by the structure (E)

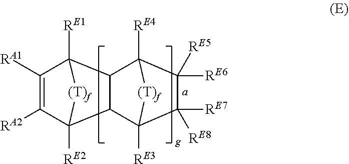

wherein

R^{E1}, R^{E2}, R^{E3}, R^{E4}, R^{E5}, R^{E6}, R^{E7}, and R^{E8} are as defined as corresponding to R^{B1} through R^{B6}.

“a” represents a single bond or a double bond;

f is 1 or 2;

g is an integer from 0 to 5, and when “a” is a double bond one of R^{E5}, R^{E6} and one of R^{E7}, R^{E8} is not present; or

(e) a mixture thereof.

### Embodiment 13

The photosensitive composition of any one of Embodiments 1 to 11, herein the unsaturated organic precursor comprises a compound having a structure:

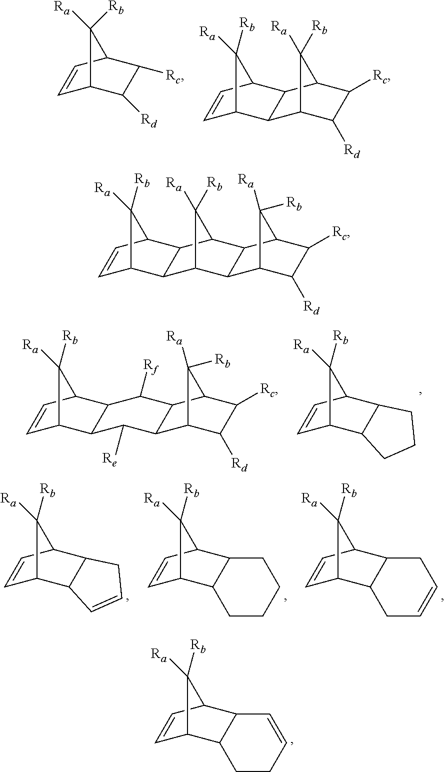

or a mixture thereof, wherein

R^{a}, R^{b}, R^{c}, R^{d}, R^{e}, and R^{f} are independently H or alkyl (preferably C₁₋₂₀ alkyl, more preferably C₁₋₁₀ alkyl.

### Embodiment 14

The photosensitive composition of any one of Embodiments 1 to 11, wherein the unsaturated organic precursor comprises a dicyclopentadiene of structure:

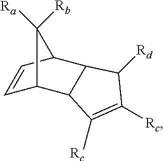

wherein

Rₐ, R_{b}, R_{c}, R_{d}, Rₑ, and R_{f} are independently H or alkyl (preferably C₁₋₂₀ alkyl, more preferably C₁₋₁₀ alkyl.

### Embodiment 15

The photosensitive composition of any one of Embodiments 1 to 14, wherein the composition has a viscosity capable of being spin coated, dip coated, or spray coated, for example with a viscosity of the composition, at the contemplated temperature of application (preferably ambient room temperature) is in a range of from about 1 cSt to about 10 cSt, from about 10 cSt to about 50 cSt, from about 50 cSt to about 100 cSt, from about 100 cSt to about 250 cSt, from about 250 cSt to about 500 cSt, from about 500 cSt to about 1000 cSt, from about 1000 cSt to about 2000 cSt, from about 2000 cSt to about 5000 cSt, or higher.

### Embodiment 16

The photosensitive composition of any one of Embodiments 1 to 15, wherein the photosensitive composition is a gelled, semi-solid or solid film.

### Photosensitive Composition Comprising Tethered Organometallic, Using any Ru-Carbene Catalyst

### Embodiment 17

The photosensitive composition of Embodiment 1 to 16, wherein the polymerizable material matrix further comprises at least one organometallic moiety having a pendant unsaturated moiety capable of metathesizing with the at least one unsaturated organic precursor, the pendant unsaturated moiety comprising at least one alkene or one alkyne bond, wherein the organometallic moiety comprises a Group 3 to Group 12 transition metal.

### Embodiment 18

The photosensitive composition of Embodiments 17, wherein the Group 3 to Group 12 transition metal is Fe, Co, Ni, Ti, Al, Cu, Zn, Ru, Rh, Ag, Ir, Pt, Au, or Hg.

### Embodiment 19

The photosensitive composition of Embodiment 17 or 18, wherein the organometallic moiety comprises a catalyst capable of catalyzing metathesis or cross-coupling reactions or splitting water.

### Embodiment 20

The photosensitive composition of any one of Embodiments 17 to 19, wherein the organometallic moiety is capable of catalyzing the oxidation or reduction of an organic substrate under oxidizing or reducing conditions.

Photosensitive composition comprising pendant functional groups

### Embodiment 21

A photosensitive composition of any one of Embodiments 1 to 20, wherein the unsaturated organic precursor has at least one mono-, di, or poly-functionalized cyclic or alicyclic alkene or one alkyne bond; and wherein the at least one unsaturated organic precursor comprises a compound having a structure:

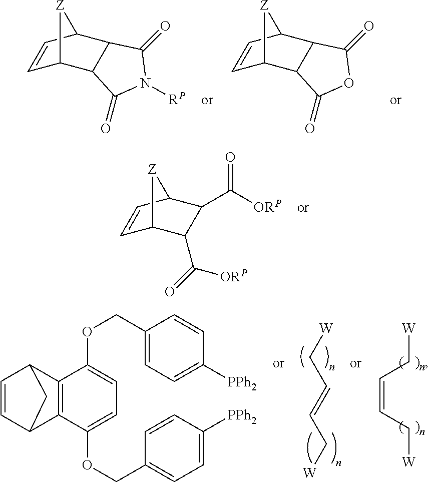

wherein

Z is —O— or C(Rₐ)(R_{b});

R^{P} is independently H; or C₁₋₆ alkyl optionally substituted at the terminus with —N(Rₐ)(R_{b}), —O—Rₐ, —C(O)O—Rₐ, —OC(O)—(C₁₋₆ alkyl), or —OC(O)—(C₆-10 aryl); or an optionally protected sequence of 3 to 10 amino acids (preferably including R-G-D or arginine-glycine-aspartic acid);

W is independently —N(Rₐ)(R_{b}), —O—Rₐ, or —C(O)O—Rₐ, —P(O)(ORₐ)₂, —SO₂(ORₐ), or SO₃;

Rₐ and R_{b} are independently H or C₁₋₆ alkyl;

the C₆₋₁₀ aryl is optionally substituted with 1, 2, 3, 4, or 5 optionally protected hydroxyl groups (the protected hydroxyl groups preferably being benzyl); and

n is independently 1, 2, 3, 4, 5, or 6.

### Embodiment 22

The composition of Embodiment 21, wherein the at least one unsaturated organic precursor comprising a compound has a structure

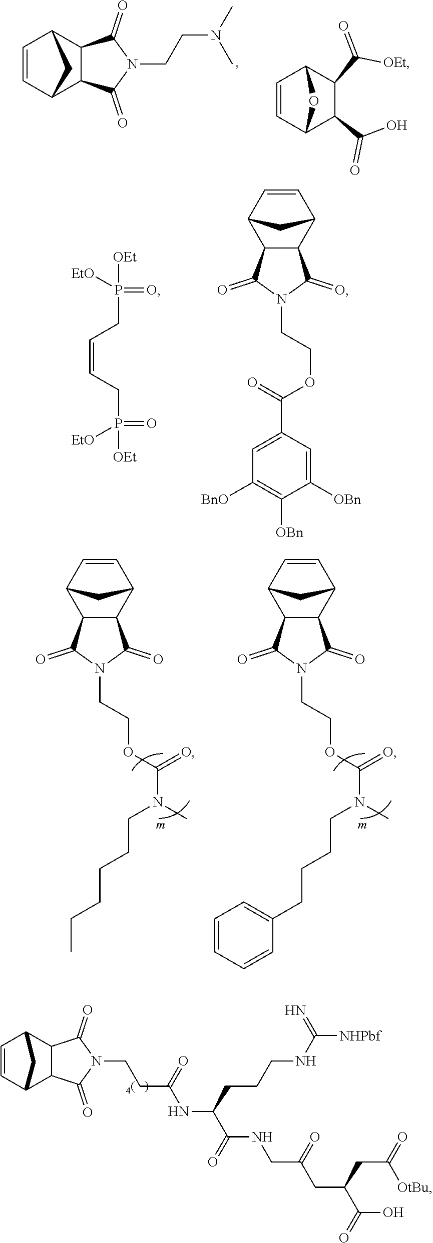

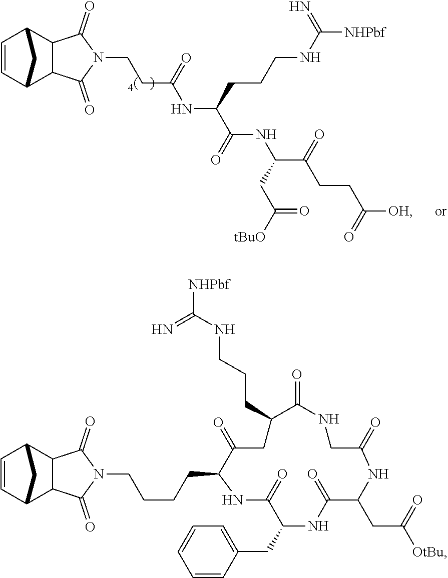

where Bn is benzyl, tBu is tert-butyl, and Pbf is 2,2,4,6,7-pentamethyldihydrobenzofuran.

### Methods of Preparing Photosensitive Composition.

### Embodiment 23

A method of patterning a polymeric image on a substrate, said method comprising;

(a) depositing one or more layers of a photosensitive composition of any one of Embodiments 1 to 22 on a substrate;

(b) irradiating a portion of the layer of photosensitive composition with a light comprising a wavelength in a range of from about 300 to about 500 nm, preferably in a range of from about 350 to about 450 nm, so as to polymerize the irradiated portion of the layer, thereby providing a patterned layer of polymerized and unpolymerized regions. In other Aspects of this Embodiment, the light comprises at least one wavelength in a range of from about 300 to about 320 nm, from about 320 to about 340 nm, from about 340 to about 360 nm, from about 360 to about 380 nm, from about 380 to about 400 nm, from about 400 to about 420 nm, from about 420 to about 440 nm, from about 440 to about 460 nm, from about 460 to about 480 nm, from about 480 to about 500 nm, or a combination thereof.

### Embodiment 24

The method of Embodiment 23, comprising depositing a plurality of layers of a photosensitive composition on a substrate before irradiation, at least one of which is a photosensitive composition of any one of Embodiments 1 to 22.

### Embodiment 25

The method of Embodiment 23 or 24, wherein the at least one layer of photosensitive composition is deposited by spin coating, dip coating, or spray coating.

### Embodiment 26

The method of Embodiment 23 or 24, wherein photosensitive composition is a gelled, semi-solid or solid film and is deposited by laminating on the substrate.

### Embodiment 27

The method of any one of Embodiments 23 to 26, wherein the irradiated portion is patterned through use of a photomask, by a direct writing application of light, by interference, nanoimprint, or diffraction gradient lithography, by inkjet 3D printing, stereolithography, holography, or digital light projection (DLP). In certain Aspects of this Embodiment, the catalysts can be activated using 2- or 3-photon energy sources at 700 to 800 nm, more specifically using a 790 nm laser.

### Embodiment 28

The method of any one of Embodiments 23 to 27, wherein the light has an intensity in a range of about 1 mW/cm² to 10 W/cm², preferably about 10 mW/cm² to 200 mW/cm² at at least one wavelength in the range of about 250 to about 800 nm, or about from about 220 to about 440 nm.

### Embodiment 29

The method of any one of Embodiments 23 to 28, wherein the patterned layer comprises at least one feature having dimensions on the nanometer or micron scale.

### Embodiment 30

The method of any one of Embodiments 23 to 29, further comprising removing the unpolymerized region of the pattern.

### Polymerized Compositions

### Embodiment 31

A polymerized composition prepared according to any one of Embodiments 23 to 29, or an article of manufacture comprising the polymerize composition.

### Embodiment 32

The polymerized composition of Embodiment 31, wherein the composition is a patterned layer.

### Embodiment 33

A tissue scaffold comprising a polymerized composition of claim 30 or 31.

### Embodiment 34

The tissue scaffold of Embodiment 33, further comprising at least one cell population.

### Method of Forming 3-D Structures of Laminated Photosensitive Compositions, Using any Ru-Carbene Catalyst

### Embodiment 35

A method comprising;

(a) depositing at least two layers of a composition having at least one alkene or alkyne capable of undergoing a metathesis polymerization or crosslinking reaction and a photoactivator admixed or dissolved therein, at least one layer comprising a composition of any one of Embodiments 1 to 22, said deposition forming a stacked assembly;

(b) irradiating at least a portion of the stacked assembly with light, such that light penetrates and irradiates at least two layers of the stacked assembly, under conditions sufficient to polymerize or crosslink at least portions of adjacent layers of the stacked assembly.

### Embodiment 36

The method of Embodiment 35, wherein light passes through and irradiates at all layers of the stacked assembly, under conditions sufficient to polymerize or crosslink at least portions of adjacent layers of the stacked assembly.

### Embodiment 37

The method of Embodiment 35 or 36, wherein the irradiating is done by patterned exposure of light to the stacked composition, so as to provide a three-dimensional pattern of polymerized and unpolymerized regions through the stacked assembly.

### Embodiment 38

The method of Embodiment 37, wherein the irradiation is patterned through use of a photomask, by a direct writing application of light, by interference, nanoimprint, or diffraction gradient lithography, by inkjet 3D printing, stereolithography, holography, or digital light projection (DLP).

### Embodiment 39

The method of any one of Embodiments 35 to 38, wherein each layer of comprises a pre-formed polymer which may be the same or different from other pre-formed polymer(s) in the other layer(s).

### Embodiment 40

The method of any one of Embodiments 35 to 39, wherein the thickness of each layer is independently on the millimeter scale (e.g., from about 1 mm to about 10 mm, from about 10 mm to about 50 mm, from about 50 mm to about 100 mm, from about 100 mm to about 500 mm, from about 500 mm to about 1000 mm, or a combination thereof), the micron scale (e.g., from about 1 micron to about 10 microns, from about 10 microns to about 50 microns, from about 50 microns to about 100 microns, from about 100 microns to about 500 microns, from about 500 microns to about 1000 microns, or a combination thereof), or the nanometer scale (e.g., in a range of from about 50 to about 100 nm, from about 100 to about 200 nm, from about 200 to about 300 nm, from about 300 to about 400 nm, from about 400 to about 500 nm, from about 500 to about 600 nm, from about 600 to about 700 nm, from about 700 to about 800 nm, from about 800 to about 900 nm, from about 900 to about 1000 nm, or a combination thereof.)

### Embodiment 41

The method of any one of Embodiments 35 to 40, wherein the polymer in at least one layer is a block copolymer.

### Embodiment 42

The method of any one of Embodiments 35 to 41, wherein the polymer is at least one layer of block copolymer, the block copolymer being a dendritic (wedge) or brush (graft, bottlebrush) copolymer.

### Embodiment 43

The method of any one of Embodiments 35 to 42, wherein the polymer is at least one layer of block copolymer exhibiting domains having dimensions in a range of from about 5 to about 1500 nanometer domains, or in a range of from about 75 to about 300 nm.

### Embodiment 44

The method of any one of Embodiments 35 to 43, wherein the polymer is derived from polymerization of a polymer precursor, and wherein unreacted polymer precursor in the layer provides the at least one alkene or alkyne in the composition.

### Embodiment 45

The method of any one of Embodiment 35 to 44, wherein adjacent layers of at least two sequentially deposited layers are compositionally different.

### Embodiment 46

The method of any one of Embodiments 35 to 45, wherein adjacent layers of at least two sequentially deposited layers are compositionally the same.

### Embodiment 47

A stacked polymer composition prepared according to any one of Embodiments 35 to 46, or an article containing said stacked polymer composition.

### Embodiment 48

A photonic structure prepared according to any one of Embodiments 35 to 46.

### Embodiment 49

A method comprising a vat photopolymerization, wherein a photosensitive composition of any one of Embodiments 1 to 22 is cured directly onto a translated or rotated substrate, and the irradiation is patterned via stereolithography, holography, or digital light projection (DLP).

### EXAMPLES

The following Examples are provided to illustrate some of the concepts described within this disclosure. While each Example is considered to provide specific individual embodiments of composition, methods of preparation and use, none of the Examples should be considered to limit the more general embodiments described herein.

In the following examples, efforts have been made to ensure accuracy with respect to numbers used (e.g. amounts, temperature, etc.) but some experimental error and deviation should be accounted for. Unless indicated otherwise, temperature is in degrees C., pressure is at or near atmospheric.

### Example 1: Screening Experiments Comparing Ruthenium Metathesis Catalysts Comprising Phenanthroline and Bipyridine Ligands

A series of photosensitive compositions were prepared using the catalysts generated in situ using Catalyst C627 and butyl vinyl ether (BVE), according to Table 1:

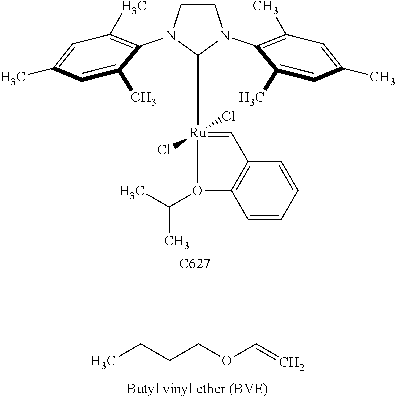

TABLE 1
Catalysts compositions prepared using 1 equivalent C627, 5
equivalents Ligand, and 10 equivalents BVE in CHCl₃; final
concentration of catalyst was equivalent to 10 mg/mL of C627.

| Ligand 1 | Ligand 2 | Ligand 3 | Ligand 4 |
|---|---|---|---|
| 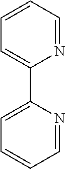 [SMILES: c1ccc(-c2ccccn2)nc1] | 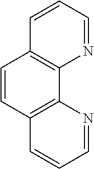 [SMILES: c1cnc2c(c1)ccc1cccnc12] | 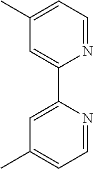 | 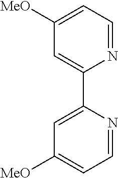 [SMILES: COc1ccnc(-c2cc(OC)ccn2)c1] |

After 18 hours of stirring the catalyst solutions at ca. 400 rpm, photopolymer solutions were prepared by adding 20 microliters of each catalyst solution to 2 mL of a dicyclopenadiene solution containing approximately 6 wt % tricyclopentadiene. The presumed latent catalysts was the corresponding butyl vinyl carbene.

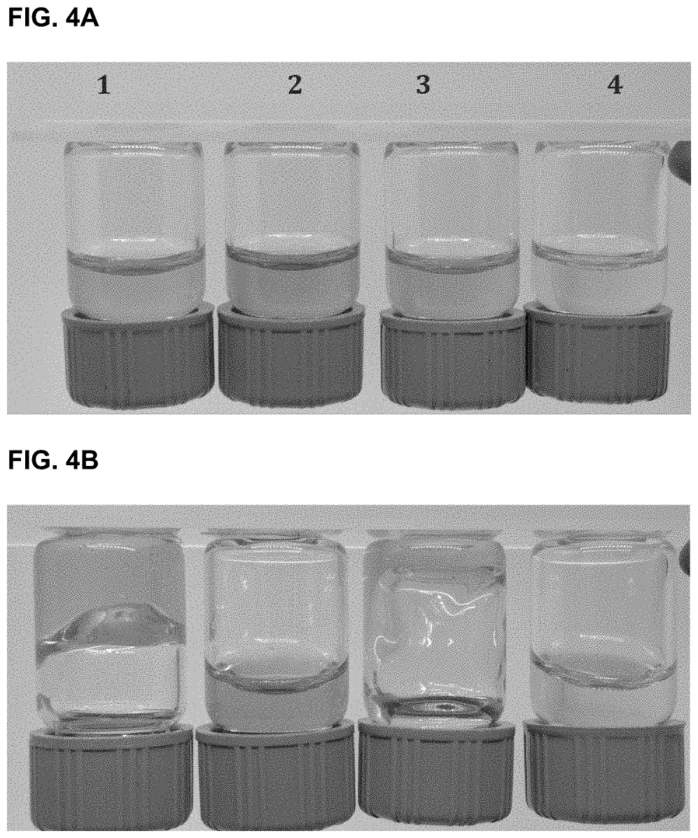

One mL of each prepared LCS resin was kept in the dark at RT for one hour, with no change in viscosity observed (FIG. 4A).

One mL of each prepared LCS resin was irradiated in vials with 1000 mJ @ 405 nm (14.6 mW, 68.5 sec), with corresponding changes in viscosity observed (FIG. 4B). The latent catalyst complex formed with 2,2′-bipyridine (1) displayed significantly faster photoinitiation than the other catalysts. It clearly gelled. The latent catalyst complex formed with 4,4′-dimethyl-2,2′-bipyridine (3) showed the initial stages of crosslinking under these conditions. The latent catalyst complexes formed with phenanthroline (2) and 4,4′-dimethoxy-2,2′-bipyridine (4) provided no evidence of viscosity change under these conditions.

### Example 2: Testing of Bathophenanthroline Chelate

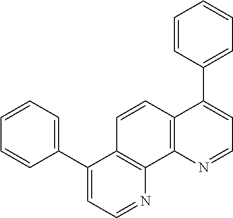 [SMILES: c1ccc(-c2ccnc3c2ccc2c(-c4ccccc4)ccnc23)cc1]

A latent catalyst solution was prepared by stirring together 23.25 mg bathophenanthroline, 29.22 mg, GrubbsII-Hoveyda C627, 15 μL butyl vinyl ether, and 0.58 mL chloroform, as described in Example 1. After stirring for 24 hours at room temperature, 8 μL of this latent catalyst solution was added to 1 mL of a dicyclopentadiene solution containing approximately 6% tricyclopentadiene. The resulting solution represented an olefin-metathesis based photopolymer resin. A drop of this solution was sandwiched between two glass slides containing a 200 micron thick spacer. After an exposure of 990 mJ/cm² at λ=405 nm at 50° C., the photopolymer liquid did not gel.

### Example 3: Testing of Phenanthroline Chelate

A latent catalyst solution was prepared by stirring together 12.37 mg phenanthroline, 28.67 mg GrubbsII-Hoveyda C627, 15 μL butyl vinyl ether, and 0.57 mL chloroform. After stirring for 24 hours at room temperature, 8 μL of this latent catalyst solution was added to 1 mL of a dicyclopentadiene solution containing approximately 6% tricyclopentadiene. The resulting solution represents an olefin-metathesis based photopolymer resin. A drop of this solution was sandwiched between two glass slides containing a 200 micron thick spacer. After an exposure of 990 mJ/cm² at λ=405 nm at 50° C., the photopolymer liquid did not gel.

### Example 4: Testing of Other Phenanthroline Derivative Chelates

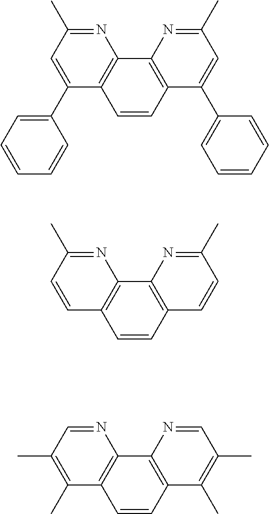

Using the procedure of Example 3, three other phenanthroline derivates were tested for photolatency. None of these catalysts polymerized the dicyclopentadiene-based resin solutions under the conditions of the test.

### Example 5: Testing of Bipyridine Chelate

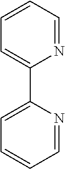 [SMILES: c1ccc(-c2ccccn2)nc1]

A latent catalyst solution was prepared by stirring together 20 mg bipyridine, 76 mg GrubbsII-Hoveyda C627, 38 μL butyl vinyl ether, and 1.50 mL chloroform. After stirring for 24 hours at room temperature, 8 μL of this latent catalyst solution was added to 1 mL of a dicyclopentadiene solution containing approximately 6% tricyclopentadiene. The resulting solution represented an olefin-metathesis based photopolymer resin. A drop of this solution was sandwiched between two glass slides containing a 200 micron thick spacer. After an exposure of 990 mJ/cm² at λ=405 nm at 50° C., the photopolymer liquid gelled.

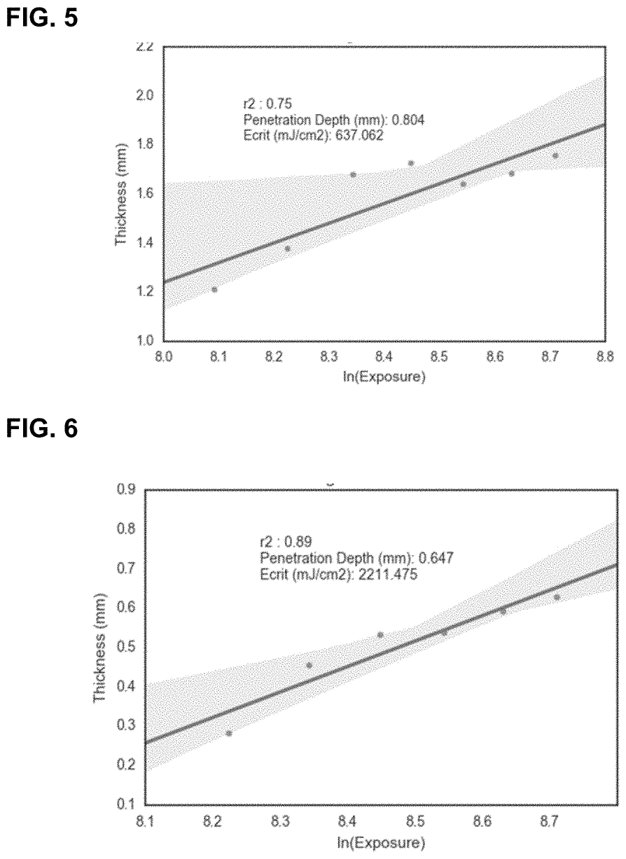

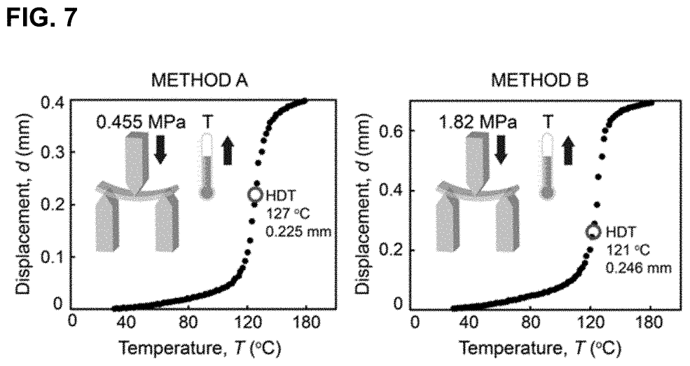

A photopolymer ‘working curve’ was created following the procedure of P. F. Jacobs (Fundamentals of Stereolithography 1992) by measuring the cure depth of the gelled material as a function of the dosage of light. The results are shown in FIG. 5.

### Example 6: Testing of 4,4′-Di-Tertbutyl-2,2′-Bipyridine Chelate

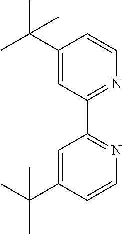 [SMILES: CC(C)(C)c1ccnc(-c2cc(C(C)(C)C)ccn2)c1]

A latent catalyst solution was prepared by stirring together 22 mg 4,4′-di-tert-butyl-2,2′-bipyridine, 26 mg GrubbsII-Hoveyda C627, 13 μL butyl vinyl ether, and 0.51 mL chloroform. After stirring for 24 hours at room temperature, 8 μL of this latent catalyst solution was added to 1 mL of a dicyclopentadiene solution containing approximately 6% tricyclopentadiene. The resulting solution represented an olefin-metathesis based photopolymer resin. A drop of this solution was sandwiched between two glass slides containing a 200 micron thick spacer. After an exposure of 990 mJ/cm² at λ=405 nm at 50° C., the photopolymer liquid gelled.

A photopolymer ‘working curve’ was created following the procedure of P. F. Jacobs (Fundamentals of Stereolithography 1992) by measuring the cure depth of the gelled material as a function of the dosage of light. The results are shown in FIG. 6.

### Example 7: Testing of 4,4′-Dibromo-2,2′-bipyridine Chelate

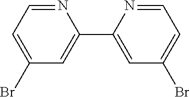 [SMILES: Brc1ccnc(-c2cc(Br)ccn2)c1]

GrubbsII-Hoveyda C627 catalyst (56 mg) and 4-4′-dibromo-2-2′-bipyridine (30 mg) were weighed into a glass vial and brought into a nitrogen purged glove box. Chloroform (1.12 mL) and 1,4-butanediol divinyl ether (28 microliters) were then added via pipette. The vial was capped, wrapped with foil to protect from ambient light and the solution stirred for 18 hours. 0.032 mL of this solution was added to 4 mL of a dicyclopentadiene solution containing approximately 6% tricyclopentadiene. A photopolymer ‘working curve’ was created using the resulting solution as described above by measuring the cure depth of the gelled material as a function of the dosage of light. The following results were obtained at 385 nm: Critical Exposure: 892.720 mJ/cm2, penetration depth=1.397 mm

### Example 8: Testing of 4,4′-Di-tertbutyl-2,2′-bipyridine Chelate

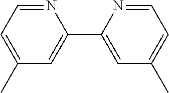

GrubbsII-Hoveyda C627 catalyst (56 mg) and 4-4′-dimethyl-2-2′-bipyridine (17.4 mg) were weighed into a glass vial and brought into a nitrogen purged glove box. 1.12 mL chloroform and 28 microliters of 1,4-Butanediol divinyl ether were then added via pipette. The vial was capped, wrapped with foil to protect from ambient light and the solution stirred for 18 hours. 0.032 mL of this solution was added to 4 mL of a dicyclopentadiene solution containing approximately 6% tricyclopentadiene. The resulting solution represents an olefin-metathesis based photopolymer resin. A photopolymer ‘working curve’ was created using the resulting solution following the procedure described above by measuring the cure depth of the gelled material as a function of the dosage of light. The following results were obtained at 385 nm: Critical Exposure: 1042.445 mJ/cm², penetration depth=1.9694 mm

### Example 8: Testing of Other Bipyridine Derivative Chelates

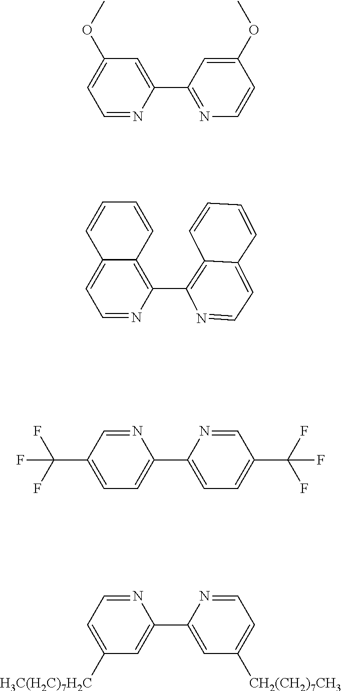

Attempts to form latent photocatalysts with four other bipyridine derivatives were surprisingly unsuccessful under the standard conditions described herein.

In the case of the 4,4′-di-methoxy-2,2′-bipyridine, under the conditions described in Examples 5-8, no measurable film was formed at exposures up to 6400 mJ/cm2 at 385 nm.

Photopolymer solutions containing the 1-(isoquinolin-1-yl)isoquinoline chelate did not form stable solutions under conditions analogous to the other substituted pyridine examples. Precipitation of the ruthenium complex made it difficult to quantify photopolymerization kinetics.

### Example 9: Stereolithographic 3D-printing

A PLOMP photopolymer prepared analogously to Example 3 was used in a Digital Light Projection (DLP, also referred to as Dynamic Micromirror Array (DMD)) stereolithographic 3D printer. A rectangular bar was printed for heat distortion temperature analysis, by irradiating 200 micron thick layers with 750 mJ/cm² of 385 nm light at a temperature of 50° C. The printed bars were subsequently heated in an oven to 160° C. to ensure the polymerization went to completion. These bars were tested using for their heat distortion temperature, as depicted in Figure ##. The following values were observed: HDT=127° C. @ 0.445 MPa, 121° C. @ 1.82 MPa

### Example 10

U.S. patent application Ser. No. 14/505,824, filed Oct. 3, 2014, which is incorporated by reference herein in its entirety, or at least for its examples, describes the use of latent Fischer-type ruthenium catalyst containing phenanthroline. One example is reiterated here as representative of the types of chemistries available with the more reactive latent ruthenium catalyst containing bipyridine ligands

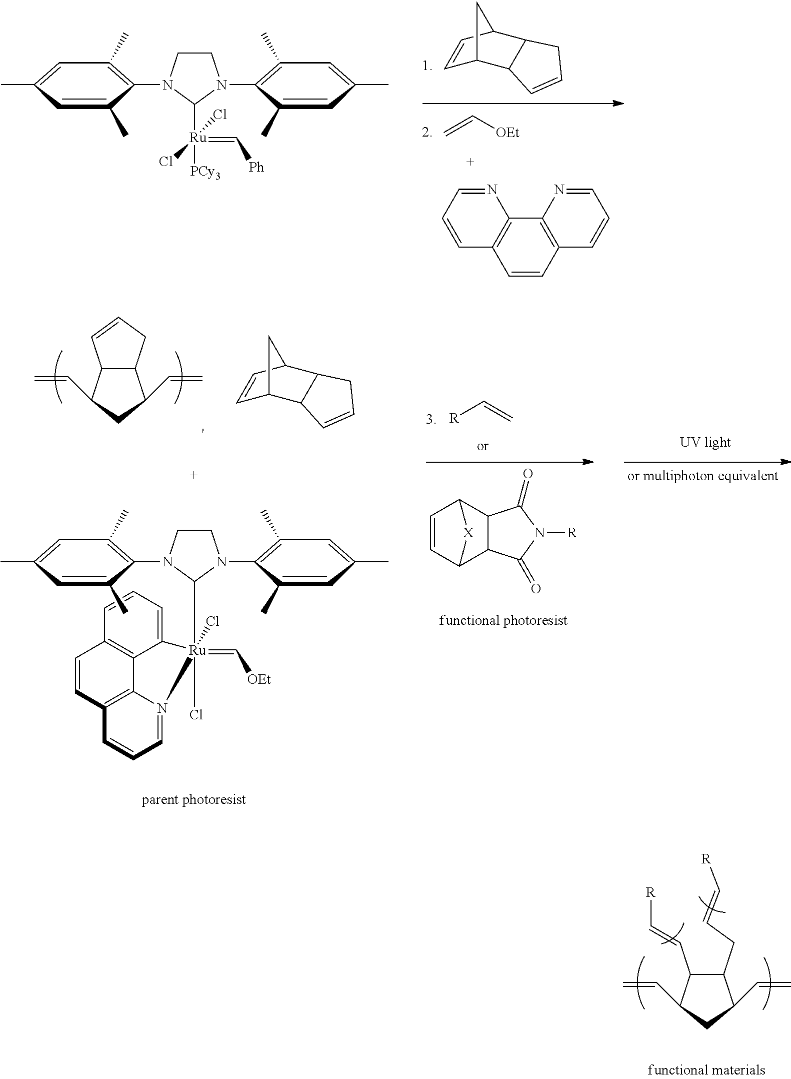

A solution of 95% dicyclopentadiene and 5% ethylidene norbornene (10 mL total, % by volume) was added to a scintillation vial and degassed with argon. The ‘Grubbs 2’ catalyst shown above (2.1 mg) was dissolved in 100 microliters of degassed chloroform, and this catalyst solution was added to the dicyclopentadiene solution while stirring under argon. At 27.5 minutes, the solution reached the desired viscosity, and the ring-opening metathesis polymerization was quenched by 2.5 mg 1,10-phenanthroline in 0.5 mL ethyl vinyl ether. The solution was stirred for 5 minutes to ensure homogeneous quenching and then stored under argon in the dark overnight before using for photolithography. This ‘parent’ photoresist could be functionalized with a wide variety of molecules without disrupting the PLOMP patterning process.

As those skilled in the art will appreciate, numerous modifications and variations of the present disclosure are possible in light of these teachings, and all such are contemplated hereby. For example, in addition to the embodiments described herein, the present disclosure contemplates and claims those inventions resulting from the combination of features of the disclosure cited herein and those of the cited prior art references which complement the features of the present disclosure. Similarly, it will be appreciated that any described material, feature, or article may be used in combination with any other material, feature, or article, and such combinations are considered within the scope of this disclosure.

The disclosures of each patent, patent application, and publication cited or described in this document are hereby incorporated herein by reference, each in its entirety, for all purposes.

What is claimed:

1. A method of preparing a three-dimensionally patterned polymer structure, the method comprising photochemically curing adjacent layers of a photosensitive composition wherein the adjacent layers are applied successively using spray coating or ink jet 3D printing or the curing of the adjacent layers is done using a vat polymerization method, the photochemical curing of the successive layers resulting in the formation of the three-dimensionally patterned polymer structure, wherein the photosensitive composition comprises a ruthenium carbene metathesis catalyst of Formula (I) or a geometric isomer thereof: 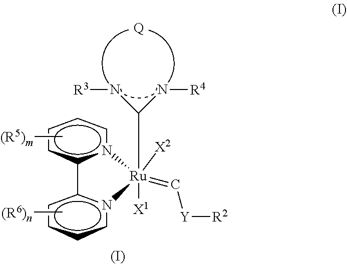
admixed within a polymerizable material matrix comprising at least one unsaturated organic precursor capable of undergoing a metathesis polymerization or crosslinking reaction;
wherein
X¹ and X² are independently anionic ligands;
Y is O, N—R¹, or S; and
Q is a two-atom linkage having the structure —CR¹¹R¹²—CR¹³R¹⁴— or —CR¹¹═CR¹³—, preferably —CR¹¹R¹²—CR¹³R¹⁴—, wherein R¹, R¹², R¹³, and R¹⁴ are independently hydrogen, hydrocarbyl, or a substituted hydrocarbyl;
R¹ and R² are independently hydrogen, optionally substituted hydrocarbyl, or may be linked together to form an optionally substituted cyclic aliphatic group;
R³ and R⁴ are independently optionally substituted hydrocarbyl; and
R⁵ and R⁶ are independently H, C₁₋₂₄alkyl, C₁₋₂₄alkoxy, C₁₋₂₄fluoroalkyl, C₁₋₂₄fluoroalkoxy, C₁₋₂₄alkylhydroxy, C₁₋₂₄alkoxyhydroxy, C₁₋₂₄fluoroalkylhydroxy(including perfluoroalkylhydroxy), C₁₋₂₄fluoroalkoxyhydroxy, halo, cyano, nitro, or hydroxy; and
m and n are independently 1, 2, 3, or 4.

2. The method of claim 1, wherein the adjacent layers are applied successively using spray coating or inkjet 3D printing to provide a stacked layer structure.

3. The method of claim 1, wherein the photosensitive composition is processed using a vat polymerization method.

4. The method of claim 3, wherein the photochemical curing is done using stereolithography, holography, or digital light projection (DLP)

5. The method of claim 3, wherein the photosensitive composition is cured directly onto a translated or rotated substrate.

6. The method of claim 1, wherein R¹ is H, R² is C₁₋₆ alkyl, and Y is O.

7. The method of claim 1, wherein Q is —CH₂—CH₂— and either R³ or R⁴, or both R³ and R⁴ are phenyl groups, optionally substituted in the 2, 6 positions with independent C₁₋₆ alkyl groups.

8. The method of claim 1, wherein Q is —CH₂—CH₂— and R³ and R⁴ are independently mesityl or optionally substituted adamantyl.

9. The method of claim 1, wherein R⁵ and R⁶ are independently H, methyl, ethyl, propyl, butyl, methoxy, trifluoromethyl, fluoro, chloro, bromo, cyano, or nitro.

10. The method of claim 1, where the metathesis catalyst comprises a catalyst represented by the structure of formula (IA):

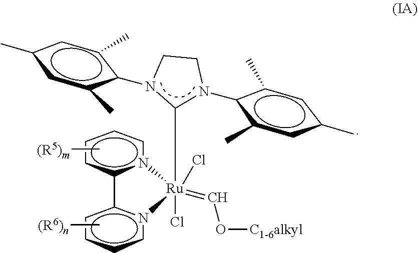

11. The method of claim 1, wherein R⁵ and R⁶ are present in the 3,3′ or 4,4′ or 5,5′ or 6,6′ position, respectively

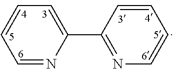 [SMILES: c1ccc(-c2ccccn2)nc1]

12. The method of claim 1, wherein the ruthenium carbene metathesis catalyst is present at a concentration in a range of from about 0.001% to about 5% by weight, relative to the weight of the photosensitive composition.

13. The method of claim 1, wherein the unsaturated organic precursor comprises a mono-unsaturated cyclic olefin; a monocyclic diene; or a bicyclic or polycyclic olefin.

14. The method of claim 1, wherein the unsaturated organic precursor is a ROMP precursor.

15. The method of claim 1, wherein the ruthenium carbene metathesis catalyst is generated in situ by the mixing of an optionally substituted 2,2′-bipyridine, a quenching agent of 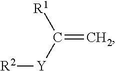
and a metathesis catalyst of Formula (IIA), (IIB), (IIIA), or (IIIB); or a geometric isomer thereof: 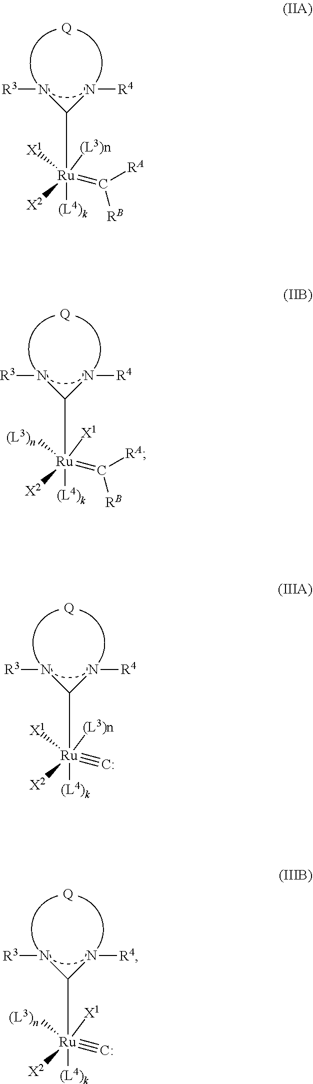
wherein:
L³ and L⁴ are independently neutral electron donor ligands;
k and n are independently 0 or 1; and
R^{A}, and R^{B} are independently hydrogen or optionally substituted hydrocarbyl, or may be linked to form an optionally substituted aromatic or aliphatic cyclic group.

16. The method of claim 1 and wherein the polymerizable material matrix further comprises at least one organometallic moiety having a pendant unsaturated moiety capable of metathesizing with the at least one unsaturated organic precursor, the pendant unsaturated moiety comprising at least one alkene or one alkyne bond, wherein the organometallic moiety comprises a Group 3 to Group 12 transition metal.

17. The method of claim 16, wherein the Group 3 to Group 12 transition metal is one or more of Fe, Co, Ni, Ti, Al, Cu, Zn, Ru, Rh, Ag, Ir, Pt, Au, or Hg.

18. The method of claim 1, wherein the at least one unsaturated organic precursor comprising a compound having a structure: 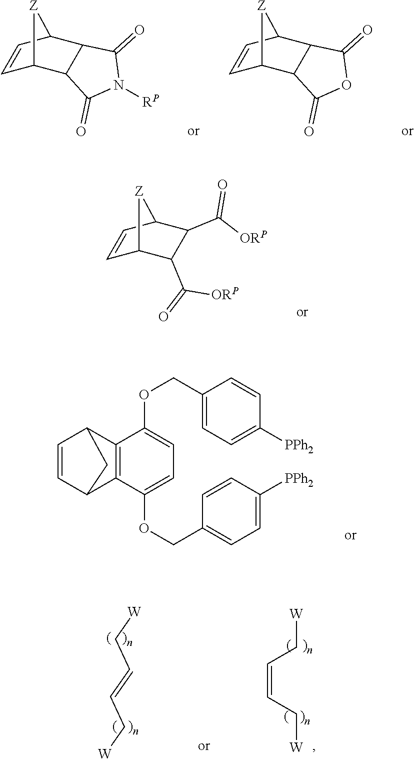
wherein
Z is —O— or C(Rₐ)(R_{b});
R^{P} is independently H; or C₁₋₆ alkyl optionally substituted at the terminus with —N(Rₐ)(R_{b}), —O—Rₐ, —C(O)O—Rₐ, —OC(O)—(C₁₋₆ alkyl), or —OC(O)—(C₆-10 aryl); or an optionally protected sequence of 3 to 10 amino acids (preferably including R-G-D or arginine-glycine-aspartic acid);
W is independently —N(Rₐ)(R_{b}), —O—Rₐ, or —C(O)O—Rₐ, —P(O)(ORₐ)₂, —SO₂(ORₐ), or SO₃⁻;
Rₐ and R_{b} are independently H or C₁₋₆ alkyl;
the C₆₋₁₀ aryl is optionally substituted with 1, 2, 3, 4, or 5 optionally protected hydroxyl groups; and
n is independently 1, 2, 3, 4, 5, or 6.

19. The method of claim 18, wherein the metathesis catalyst is represented by the structure: 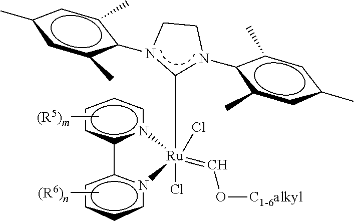
or a geometric isomer thereof.

20. The method of claim 1, wherein the photochemical curing comprises irradiating the adjacent layers of the photosensitive composition with a light comprising a wavelength in a range of from about 250 to about 500 nm, so as to polymerize the irradiated portion of a layer.

21. The method of claim 20, wherein the light comprises a wavelength in a range of from about 340 nm to about 460 nm.

22. The method of claim 20, wherein the photochemical curing of the adjacent layers is done using the patterned application of the light using photolithography, interference lithography, proximity field nanopatterning, diffraction gradient lithography, a direct laser writing application of light, nanoimprint lithography, stereolithography, or digital light projection.

23. A three-dimensionally patterned polymer structure prepared according to the method of claim 1.

24. A photonic or chemochromic structure comprising the three-dimensionally patterned polymer structure of claim 23.
